(19) United States
(12) Patent Application Publication
(10) Pub. No.: US 2026/0287658 A1
(43) Pub. Date: Sep. 24, 2026

(54) SYSTEM AND METHOD FOR MOTOR FAULT DETECTION USING HYBRID PHYSICS-BASED AND DATA-DRIVEN METHOD

(71) Applicant: Mitsubishi Electric Research Laboratories, Inc., Cambridge, MA (US)

(72) Inventors: Bingnan Wang, Boston, MA (US); Dai-Yan Ji, Greenbelt, MD (US)

(73) Assignee: Mitsubishi Electric Research Laboratories, Inc., Cambridge, MA (US)

(21) Appl. No.: 19/087,017

(22) Filed: Mar. 21, 2025

(51) Int. Cl. G01R 31/34; G06N 20/00

(52) U.S. Cl. CPC G01R 31/343; G06N 20/00

(57) ABSTRACT

A method for motor fault detection using hybrid physics based and data driven method comprises collecting synthetic data representing fault conditions of the motor using a physics-based simulation model of a type of the motor. The method further comprises collecting a batch of real-world data representing measurements of the operations of the motor including operations of the motor under normal conditions. Domain adaptation is applied to align a distribution of features in the synthetic data with a distribution of features in the batch of real-world data. The method further comprises training a machine learning model using the domain-adapted synthetic data. The faults conditions are detected in the motor by applying the trained machine learning model to real-time operational data measured during the operations of the electric motor.

### TECHNICAL FIELD

The present disclosure is generally related to machine learning-based approaches for monitoring motor health condition, and more particularly to systems and methods for aligning synthetic and real-world data for motor fault detection.

### BACKGROUND

Rotating machinery, including induction motors, form the backbone of industrial operations across sectors such as manufacturing, energy, and transportation. Motors are integral to numerous industrial applications and electrified transportation systems. For example, induction motors are widely used in various industries due to their robust design, low maintenance requirements, and cost-effective operation. Such machines rely on components such as bearings, to ensure efficient and reliable operation. However, such machines often operate under harsh conditions such as high ambient temperature, high moisture, and overload. Such adverse environments can lead to various motor faults, such as bearing wear, insulation ageing, and eccentricity, etc. These faults pose significant risks, including equipment downtime, safety hazards, and increased maintenance costs and therefore accurate detection of the occurrence and severity levels of such faults is essential for several reasons.

Currently available solutions for motors fault detection rely on sensing perceivable modalities such as vibration and acoustic emissions. However, the underlying sensor signals are often affected by various factors, such as the mounting location of the sensors. For example, physical-model-based approaches, which describe motor faults using detailed fault signatures, are increasingly reliant on experimental measurements and data analysis in order to obtain and extract the required signals. Data-driven approaches rely on the available experiment data to train a data-driven model to make decisions on the motor fault condition. Signal processing and machine learning based approaches such as those using artificial neural networks (ANN), principal component analysis (PCA), and support vector machines (SVM) struggle under diverse operating conditions and noisy environments. Accordingly, robust and efficient approaches for detecting motor faults and determining the severity levels of the faults are still desired.

### SUMMARY

Various example embodiments are directed towards detecting motor faults by combining physics-based and data-driven approaches to improve fault detection performance and generalization capability. One key challenge in motor fault detection is the scarcity of real-world data representing faulty conditions. Most motors operate in healthy states, and collecting data under faulty conditions is impractical and risky. As a result, machine learning models trained solely on real-world data often fail to generalize well to unseen faults. To address the issue, some embodiments incorporate synthetic data generation through physics-based simulations, which provide insights into various fault scenarios that are rare or difficult to capture experimentally. However, physics-based models are often simplified representations of real-world systems, leading to discrepancies between synthetic and actual motor data. This mismatch, known as the simulation-to-reality gap, limits the direct applicability of synthetic data for machine learning model training.

To bridge this gap, some embodiments apply domain adaptation techniques to align synthetic data distributions with real-world measurements. By leveraging a small amount of real-world data, the synthetic data is fine-tuned using methods such as optimal transport, ensuring that its statistical properties align with actual motor operations. This alignment enhances the utility of the synthetic data, making a valuable resource for training machine learning models.

Additionally, some embodiments provide a system incorporating Topological Data Analysis (TDA), a technique used for transformation of time-series motor data into topological representations, enabling the extraction of fault-related features. By combining physics-based simulations, domain adaptation, Fourier transform, direct quadrature transformation and advanced signal analysis techniques such as TDA, the disclosed embodiments create a hybrid fault detection system enhancing the robustness of the machine learning models by providing a balanced dataset representing both simulated and real-world conditions. The system reduces dependency on large volumes of real-world data, which may be expensive and time-consuming to collect. The system enables the detection of gradual fault conditions, such as varying levels of motor eccentricity, with higher precision. The capability is advantageous in applications where early fault detection prevent costly damage and downtime. Ultimately, the system capitalizes on the strengths of both synthetic and real-world data while addressing their individual limitations.

TDA is a mathematical process for extracting shape information from a data space. TDA may be applied to time-series data, image data, sensor data, and the likes for extracting intrinsic geometric properties of objects. Some embodiments recognize that motor signals, such as three-phase currents, exhibit intricate temporal structures that encode essential (e.g., amplitude variations, phase shifts, frequency components, and transient anomalies) information about the motor's operating condition. These structures may be mapped into higher-dimensional spaces, where TDA techniques such as persistent homology are applied to extract meaningful topological features.

Domain adaptation is a mathematical approach used to align the distributions of data from different domains, ensuring that machine learning models trained on one type of data (e.g., synthetic data) may generalize effectively to another type of data (e.g., real-world data). Optimal transport (OT) provides a principled way to minimize the discrepancy between probability distributions by computing the efficient way to transform one distribution into another. Optimal transport is based on the idea of finding a mapping which minimizes the transportation cost between two probability distributions. Mathematically, the OT involves solving a constrained optimization problem where the cost function quantifies the effort required to move data points from the synthetic domain to the real-world domain. By minimizing the cost, optimal transport facilitates that the adapted synthetic data aligns closely with real-world motor signals in terms of statistical properties and feature distribution.

Various example embodiments include MWFM method. The Modified Winding Function Method (MWFM) is a physics-based approach used in the simulation model to compute motor inductance variations under different fault conditions. The MWFM considers the effects of rotor eccentricity, non-uniform air-gap distribution, and winding configurations to generate synthetic current signals representing faulty motor behavior. MWFM calculates inductance matrices by integrating winding functions and air-gap permeance functions over the stator angles, allowing for a detailed representation of electrical characteristics under faults. The generated synthetic data may be used to train fault detection models.

Various embodiments are based on the realization that Direct-Quadrature (DQ) Transformation, also known as the Park Transformation, is a mathematical technique used in electrical engineering to simplify the analysis and control of three-phase AC systems, including electric motors. The DQ transformation method transforms three-phase time-domain signals (typically in the abc reference frame) into a two-axis rotating reference frame (d-q coordinates), making easier to analyze electrical quantities such as voltage, current, and flux.

Accordingly, one embodiment discloses a method for detecting faults in operations of a motor. The method uses a processor coupled with stored instructions implementing the method. The instructions when executed by the processor carry out steps of the method comprises collecting synthetic data representing fault conditions of the motor using a physics-based simulation model of a type of the motor. The method further comprises collecting a batch of real-world data representing measurements of the operations of the motor including operations of the motor under normal conditions. The method further comprises applying a domain adaptation to align a distribution of features in the synthetic data with a distribution of features in the batch of real-world data. The method further comprises training a machine learning model using the domain-adapted synthetic data. The method further comprises detecting fault conditions in the motor by applying the trained machine learning model to real-time operational data measured during the operations of the electric motor.

### BRIEF DESCRIPTON OF THE DRAWINGS

The presently disclosed embodiments will be further explained with reference to the following drawings. The drawings shown are not necessarily to scale, with emphasis instead generally being placed upon illustrating the principles of the presently disclosed embodiments.

FIG. 1A illustrates schematics of a system for fault detection in an induction motor, according to one embodiment;

FIG. 1B illustrates a flowchart of a method for motor fault detection using hybrid physics based and data driven method, according to some embodiments;

FIG. 1C illustrates schematics of a system for fault detection in an induction motor at runtime, according to one embodiment;

FIG. 1D illustrates a flowchart of a method for motor fault detection using hybrid physics based and data driven method, according to some embodiments;

FIG. 2 illustrates a flowchart of a method for motor fault detection using Topological Data Analysis (TDA), according to some embodiments;

FIG. 3 illustrates a framework for motor fault detection using hybrid physics based and data driven method, according to one embodiment;

FIG. 4 illustrates a framework of simulation process using MWFM method, according to one embodiment;

FIG. 5A is a diagram illustrating a framework for signal preprocessing and feature extraction process using DQ transformation, according to one embodiment;

FIGS. 5B and 5C jointly illustrate a table of feature extraction from ia and i_{q} signals, according to one embodiment;

FIG. 6A is a diagram illustrating a framework for signal preprocessing and feature extraction process using free spectrum analysis, according to some embodiments;

FIG. 6B illustrates a table of features extracted from frequency spectrum, according to some embodiments;

FIG. 7A is a diagram illustrating a framework for signal preprocessing and feature extraction process using topological data analysis, according to one embodiment;

FIG. 7B illustrates a table of features extracted from H₀ and H₁ betti curves, according to one embodiment;

FIG. 8 is a diagram illustrating a combined methods of signal preprocessing and feature extraction, according to some embodiments;

FIG. 9 is a flowchart illustrating domain adaptation method using optimal transport technique, according to some embodiments;

FIG. 10 illustrates a use case for motor fault detection in a factory automation system, according to one embodiment; and

FIG. 11 illustrates schematics of some components of a system for motor fault detection using hybrid physics based and data driven method, according to some embodiments.

### DETAILED DESCRIPTION

The following description provides exemplary embodiments only, and is not intended to limit the scope, applicability, or configuration of the disclosure. Rather, the following description of the exemplary embodiments will provide those skilled in the art with an enabling description for implementing one or more exemplary embodiments. Contemplated are various changes that may be made in the function and arrangement of elements without departing from the spirit and scope of the subject matter disclosed as set forth in the appended claims.

Specific details are given in the following description to provide a thorough understanding of the embodiments. However, understood by one of ordinary skill in the art can be that the embodiments may be practiced without these specific details. For example, systems, processes, and other elements in the subject matter disclosed may be shown as components in block diagram form in order not to obscure the embodiments in unnecessary detail. In other instances, well-known processes, structures, and techniques may be shown without unnecessary detail in order to avoid obscuring the embodiments. Further, like-reference numbers and designations in the various drawings may indicate like elements.

Also, individual embodiments may be described as a process which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process may be terminated when its operations are completed but may have additional steps not discussed or included in a figure. Furthermore, not all operations in any particularly described process may occur in all embodiments. A process may correspond to a method, a function, a procedure, a subroutine, a subprogram, etc. When a process corresponds to a function, the function's termination can correspond to a return of the function to the calling function or the main function.

Furthermore, embodiments of the subject matter disclosed may be implemented, at least in part, either manually or automatically. Manual or automatic implementations may be executed, or at least assisted, through the use of machines, hardware, software, firmware, middleware, microcode, hardware description languages, or any combination thereof. When implemented in software, firmware, middleware or microcode, the program code or code segments to perform the necessary tasks may be stored in a machine-readable medium. A processor(s) may perform the necessary tasks.

### Overview

Induction motors are indispensable in real-world applications. These motors play a pivotal role in driving machinery and ensuring the smooth operation of processes in various sectors, including manufacturing, transportation, and energy. Motors are critical components in various industrial and transportation systems due to their robustness, efficiency, and versatility. Mostly, motors are used for driving loads at variable speeds and therefore they are subject to severe mechanical stress, wear and tear, and often exposed to harsh operating conditions such as high ambient temperatures, excessive moisture, mechanical overloads, and fluctuating loads. Over time, these conditions can lead to structural as well as operational faults, including bearing wear, rotor eccentricity, and insulation aging. Such faults manifest in the performance of the motor, making the motor vulnerable to breakdown and unfit for the intended application.

In fact, motor faults are a leading cause of equipment failure, resulting in significant downtime, costly repairs, and safety hazards. For example, bearing failures are the common causes of downtime and maintenance in industrial equipment. Even minor defects in the bearing surface can propagate over time, leading to increased friction, heat generation, and vibrations that can affect the motor's overall performance. Some embodiments are based on the realization that systems for monitoring and diagnosis of motor health is required for minimizing unexpected failures, reducing maintenance costs, and optimizing operational efficiency of induction machines. Detecting these faults prevents failures and optimizes maintenance.

Available fault detection methods such as motor current signature analysis (MCSA) detect motor faults based on the measured motor current data, and require no additional sensor installation. One main challenge with MCSA is that the fault signals are often much smaller and dominated by the fundamental component and its harmonics. In addition, it is impossible to have a model to completely describe all the conditions in the physical motor system, and there are always discrepancies between physical models and real system. Various embodiments realize that fault signals in real data may be different than those identified with physical model, and is difficult to identify the fault signals in real data and determine the fault condition based only on physical models.

Some embodiments recognize to incorporate synthetic data generation where the data generated through simulations offers a promising way to overcome the limitation. Simulated data provide rich information about various fault scenarios, including those that are rare or difficult to replicate experimentally. However, some embodiments realize that simulation models are imperfect representations of real-world systems. The simulation models simplify complex dynamics, resulting in discrepancies between the synthetic data and real-world observations. This divergence, known as the simulation-to-reality gap, may severely limit the direct applicability of synthetic data for training machine learning models. The recognition of this gap and its impact on predictive accuracy is a pivotal insight that guides the need for adaptation methods.

It is a realization of various embodiments that the available methods such as phenomenological models for vibration signal simulation, have limitations. These models rely on mathematical functions to generate synthetic data but often fail to capture real fault characteristics accurately. Deep learning-based domain adaptation techniques have been used, but they require large datasets and extensive processing. Some methods simulate motor current signals under healthy conditions but lack the ability to generate faulty-condition data.

Some embodiments are based on the realization that fault-related features in motor data are often subtle and buried within noise, making difficult to detect using standard preprocessing techniques. Various embodiments realize that Topological Data Analysis (TDA) has emerged as a powerful tool for uncovering the hidden patterns. TDA transforms time-series data into topological representations, enabling the extraction of features such as persistence and connectivity that are indicative of fault conditions. While TDA is effective in revealing fault-related characteristics, its application to synthetic data alone may produce features which do not perfectly match those derived from real data. The mismatch underscores the necessity of aligning synthetic data with real-world measurements to enhance its utility.

Various embodiments are based on the realization that adapted synthetic data bridges the simulation-to-reality gap, enabling machine learning models to generalize fault detection across real-world conditions. Some embodiments are based on realizing that this gap may be bridged using domain adaptation techniques. Various embodiments address the challenge of detecting motor faults using physics based and data driven based approaches. To address this challenge, a fault detection method is introduced which combines physics-based and data-driven approaches for the fault detection performance and the generalization capability. By using a small amount of real-world data, it becomes possible to adjust the distribution of synthetic data so that it more closely aligns with real measurements. The method leverages advanced mathematical tools, such as optimal transport, to map the features from the synthetic domain to the real domain. It is a realization of various embodiments that the feasibility of the method arises from the observation real data capture fault characteristics, even in limited samples. These characteristics act as anchors, allowing the synthetic data to be fine-tuned and enriched with the authenticity of real-world conditions.

Some embodiments are based on another realization that machine learning models trained on experiment data, have the capability of extracting latent features in high-dimensional data related to the fault condition of the machine, and perform fault classification or regression tasks. However, for such data-driven approach to work with reasonable accuracy, sufficient measurement data are needed to train the models. In the case of electric machines, measurement data from faulty conditions are particularly difficult to obtain, as most data are collected when the machines are healthy. Various embodiments recognize that data-driven approaches are limited generalization capability. Models that are trained and work well on one particular dataset often do not work on new datasets that are not seen by the model before.

The fault detection method utilizes a physics-based simulation model to generate synthetic data for a machine under various fault conditions. While the model can reasonably simulate the fault condition, there are unavoidably discrepancies between simulation and real. The method applies domain adaptation techniques to bridge the gap between simulation and real data. Various data pre-processing and feature extraction methods are applied to the raw time-domain data obtained by simulations and measurements alike, before feeding the data to DA process, which largely reduce the dimensions of the raw data, extract the fault related features, and make the whole process efficient. The simulation data are more aligned with real data. The method includes training machine learning models to make predictions for the machine fault condition. The machine learning model is deployed for fault detection, where it takes in the real data, and make predictions for the fault condition of the machine.

### Motor Control System and Method

It is an object of some embodiment to provide a system and a method for estimating not only the presence or absence of one or more faults in an induction motor but also the level of severity of the one or more faults. Additionally, some embodiments also provide measures for controlling the motor to combat or address the one or more faults. Some examples of the measures include altering the speed of the motor, changing the voltage, current, or phase of the input to the motor, or recommending modifications to the structure and design of the motor.

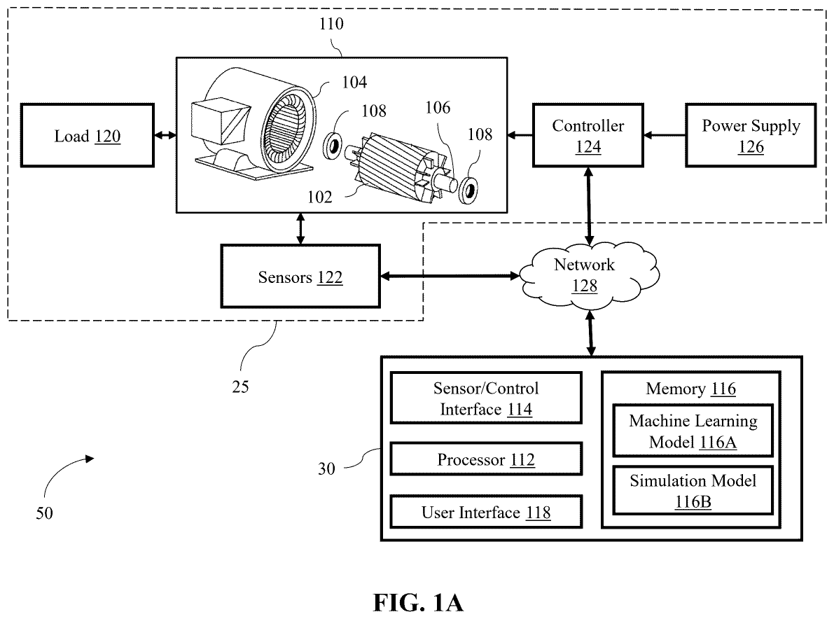

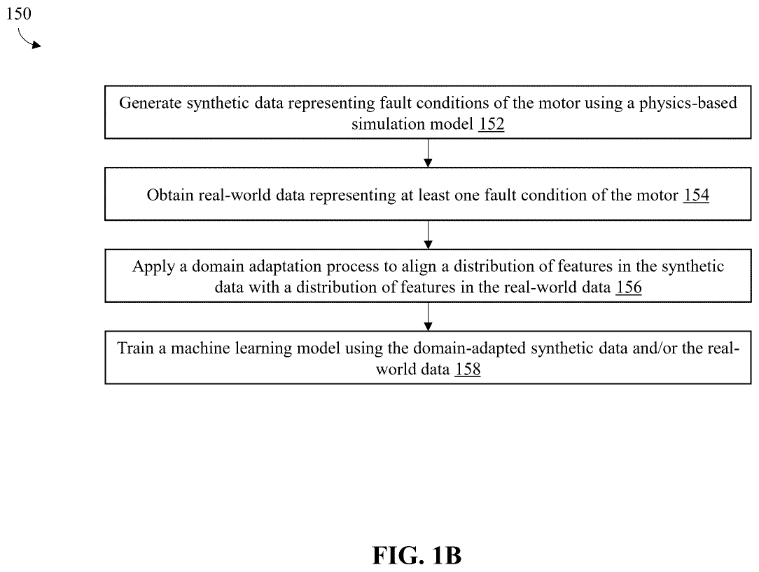

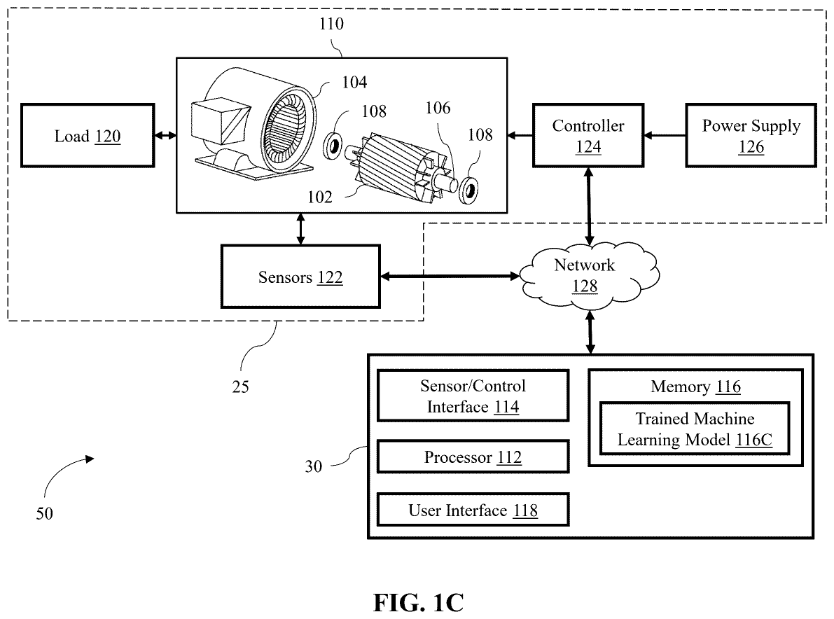

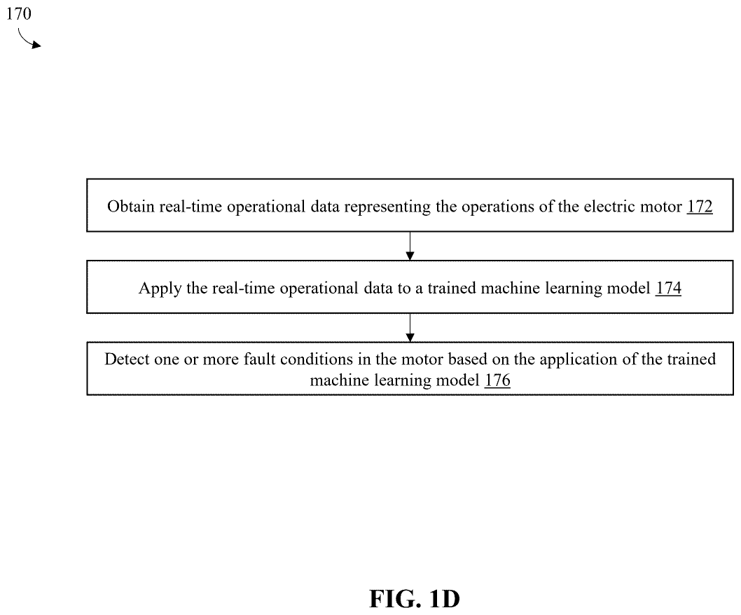

FIG. 1A illustrates a block diagram of a system 50 for fault detection in an induction motor 110, according to some embodiments. The system 50 may comprise a motor system 25 and a motor fault detection system 30. The motor system 25 and the motor fault detection system 30 may be communicatively coupled with each other through a network 128. The motor system 25 comprises an induction machine such as an induction motor 110 driving a load 120, a plurality of sensors 122, a motor controller 124, and a power supply 126. The motor fault detection system 30 comprises a sensor/control interface 114, a processor 112, a user interface 118, and a memory 116. In some embodiments, the motor controller 124 may receive input commands from a user or other computer program and compute reference values for the torque and speed of the motor 110.

The induction motor (system) 110 includes a rotor assembly 102, a stator assembly 104, a main shaft 106, and two main bearings 108. In this example, the induction motor 110 is a squirrel-cage induction motor, however, other configurations of the induction motor 110 may also be used.

The memory 116 includes a machine learning model 116A and a simulation model 116B. The memory 116 stores the data hosting specialized modules that drive the intelligence of the system. The simulation model 116B generates synthetic motor fault data under various conditions, while the machine learning model 116A is trained to detect faults by learning patterns from both synthetic and real data. The memory 116 stores instructions that are executable by the system 30 and any data that may be utilized by the methods and systems of the present disclosure. The memory 116 may include random access memory (RAM), read only memory (ROM), flash memory, or any other suitable memory systems. The memory 116 may be a volatile memory unit or units, and/or a non-volatile memory unit or units. The memory 116 may also be another form of computer-readable medium, such as a magnetic or optical disk. The memory 116 stores algorithms and data, including domain adaptation methods for aligning synthetic and real-world data, Direct-Quadrature (DQ) transformation methods for signal processing, and feature extraction techniques for identifying fault-related patterns in motor data, as well as historical fault data for pattern recognition and predictive maintenance.

Sensors 122 may be randomly or strategically placed to monitor the motor's operational parameters, such as vibration, current, temperature, and acoustic emissions. These sensors provide multimodal data, capturing distinct yet interconnected aspects of the motor's performance. For example, vibration sensors may aid in the detection of mechanical irregularities such as bearing faults, while current sensors may aid in the identification of electrical anomalies, and temperature sensors may track overheating issues. Additionally, acoustic sensors may further enhance fault detection by capturing sound patterns indicative of specific problems. It may be contemplated that the sensors 122 may not be limited to the above-mentioned sensors; instead within the scope of this disclosure, they may as well include other sensors used with motors. The sensor data from the sensors 122 may be transmitted through a network 128 to the controller 124 that processes the incoming data.

The controller 124 may be powered by a power supply 126, ensuring consistent operation even under varying conditions. The controller 124 manages the coordination between data acquisition, analysis, and fault detection algorithms. The controller 124 may be used for monitoring and controlling the operation of the induction motor 110 in response to various inputs. For example, the controller 124 connected to the induction motor 110 may control the speed of the induction motor based on inputs received from the fault detection system 30 configured to acquire data pertaining to operating conditions of the induction motor 110 from the sensors 122. According to some embodiments, the electrical signal of the sensors 122 may be current and voltage values pertaining to the induction motor 110. For example, a current sensor may sense current data from one or more of the multiple phases of the induction motor 110. More specifically, in the case the induction motor 110 is a 3-phase induction motor, the current and voltage sensors sense the current and voltage data from the three phases of the 3-phase induction motor

The processor 112 is configured to execute instructions and perform advanced computations required for fault analysis. The processor 112 processes data received from sensors 122, which include vibration sensors, current sensors, temperature sensors, acoustic sensors, and optionally speed or position sensors. These sensors monitor various aspects of the motor's performance, such as mechanical vibrations, electrical current, heat levels, and sound patterns. By analyzing the hybrid adapted data, the processor identifies potential faults and optimizes the fault detection process.

The processor 112 employs advanced algorithms, including domain adaptation methods for aligning synthetic and real-world data, Direct-Quadrature (DQ) transformation methods for signal processing. Furthermore, the processor 112 integrates feature extraction techniques for identifying fault-related patterns in motor data. The processor 112 also manages predictive analytics, leveraging historical and real-time data to estimate fault severity and forecast potential failures, enabling proactive maintenance. In addition to data analysis, the processor 112 oversees the coordination of system components. The processor 112 communicates with the controller 124 to ensure seamless operation and interacts with the user interface 118 to provide real-time updates, fault alerts, and actionable insights.

The user interface 118 enables seamless interaction between the motor fault detection system 30 and operators, providing an intuitive platform for monitoring and control. The user interface 118 facilitates the output of real-time sensor data, fault detection outcomes, and actionable insights, ensuring that operators can effectively monitor the motor's performance and respond to potential issues promptly. Additionally, the user interace 118 allows operators and users to configure system settings, such as sensor parameters, alert thresholds, and fault classification preferences. The user interface 118 is designed to communicate with the processor 112, receiving processed data and transmitting commands or configurations as needed. Through its integration with the network 128, the user interface 118 ensures a smooth exchange of information with other system components, including the sensors 122, the controller 124, and the memory 116. The user interface 118 may be implemented through various platforms, such as touchscreens, desktop applications, or mobile devices, providing flexibility for on-site or remote monitoring.

The network 128 facilitates seamless communication between various components such as sensors 122, processor 112, controller 124, memory 116, and user interface 118. The network 128 enables data transmission, command execution, and coordination of system functions over wired or wireless channels, ensuring efficient and reliable operation. The network 128 may be implemented using multiple technologies to meet different operational requirements. For stationary systems, wired solutions such as Ethernet provide high-speed, secure, and stable connections. On the other hand, wireless technologies such as Wi-Fi, Zigbee, Bluetooth, or cellular networks (e.g., 4G/5G) are ideal for applications requiring mobility, flexibility, or remote monitoring capabilities. The network 128 may include hardware components such as routers, modems, or wireless transceivers, ensuring robust connectivity between system modules and external systems. In addition to hardware, the network 128 incorporates software for data management, including packetizing and de-packetizing sensor data, controlling communication protocols, and integrating with cloud platforms for remote access and advanced analytics. The network 128 may also utilize advanced configurations, such as software-defined networking (SDN), to optimize data flow and improve scalability. By enabling real-time data transfer between sensors 122, the processor 112, and user interface 118, the network 128 ensures that insights, such as fault detection and diagnostics, are promptly available. Moreover, the network 128 supports external connectivity, allowing integration with cloud-based systems for data storage, remote monitoring, and predictive analytics.

The load 120 may be a mechanical or movable component that is driven by the motor 110. Depending on the application, the load 120 may be a conveyor belt, pump, fan, or industrial machinery. The system 50 ensures the motor operates efficiently under varying load conditions, monitoring its behavior through the integrated sensors 122. By analyzing data from the sensors, the system 50 may detect anomalies caused by load variations, such as overloads or imbalances.

The power supply 126 provides the necessary electrical energy to operate the motor 110, sensors 122, and the system's 50 control components. The power supply 126 may be configured for alternating current (AC) or direct current (DC) operation, depending on the motor type and application. The power supply 126 ensures stable voltage and current delivery to avoid operational disruptions. In some cases, the power supply 126 may include features such as surge protection, voltage regulation, or backup battery systems to enhance reliability.

The motor 110 serves as a component for converting electrical energy into mechanical energy to drive the connected load 120. In some embodiments, the motor may be configured as an induction motor, synchronous motor, or brushless DC motor, depending on the specific application requirements. The motor 110 includes integral components such as the rotor 102, which rotates to generate mechanical torque, and the bearings 108, which provide support and facilitate smooth rotational movement while reducing friction. Surrounding the rotor 102 is the stator, which contains the stationary windings that interact with the rotor 102 to produce motion. Sensors 122 are strategically placed within the system 50 to monitor parameters such as vibration, temperature, current, and rotational speed, enabling the detection of potential faults such as misalignments, overheating, or mechanical wear in components such as the bearings 108. In some embodiments, the controller 124 processes this sensor data, along with computations from the processor 112.

The sensor/control interface 114 acts as the communication hub between the sensors 122 and the processor 112. As an interface for sensors, the sensor/control interface 114 collects data from various sensors and transmits the data to the processor 112 for analysis. The sensor/control interface 114 may support multiple communication protocols, such as CAN bus, Modbus, or Ethernet, enabling seamless integration with diverse sensor types. In addition, the sensor/control interface 114 ensures accurate synchronization of data collection, reducing latency and improving fault detection efficiency. As an interface for control actions, the sensor/control interface 114 allows the processor 112 to send commands to the controller 124, enabling real-time adjustments in motor operation.

The motor controller 124 controls the operation of the motor 110. For example, the controller 124 may adjust parameters such as speed, torque, and direction of rotation of the motor based on inputs from the processor 112 and sensors 122. The controller 124 plays a key role in maintaining motor efficiency and stability, especially under varying load conditions. For advanced applications, the controller 124 may include features such as field-oriented control (FOC) for high-performance motor control or adaptive algorithms for handling dynamic conditions. The controller 124 communicates with the processor 112 via the network 128 to ensure that operational adjustments align with diagnostic insights.

When the fault-detection system 30 determines that a fault is caused based on the sensor signals of the sensors 122 during the operation of the induction machine (induction motor 110), the fault-detection system 30 may transmit a control signal via the network 128 to slow down or stop driving the induction motor 110 based on a preprogrammed algorithm (not shown) stored in the memory 116.

FIG. 1B illustrates a flowchart of a method 150 for motor fault detection using hybrid physics based and data driven method, according to some embodiments. FIG. 1B is described with reference to one or more elements from FIG. 1A. At 152, the method 150 comprises generating synthetic data representing fault conditions of the motor using a physics-based simulation model. The simulation model is designed to replicate real-world motor behavior under various faulty conditions, such as bearing faults, broken rotor bars, misalignment, and insulation degradation. The input to the simulation model includes motor fault conditions such as load conditions, motor design parameters, and supply voltage, which influence the behavior of the motor under different fault scenarios. Motor design parameters include stator and rotor geometry, number of windings turns, core material properties, air gap length, pole pairs, and winding configuration. These parameters define the motor's fundamental structure and electromagnetic behavior, which influence the response to faults. Load conditions include mechanical load torque, inertia, friction, and external disturbances that affect motor operation. These conditions impact how faults such as bearing wear, unbalanced loads, and misalignment develop over time.

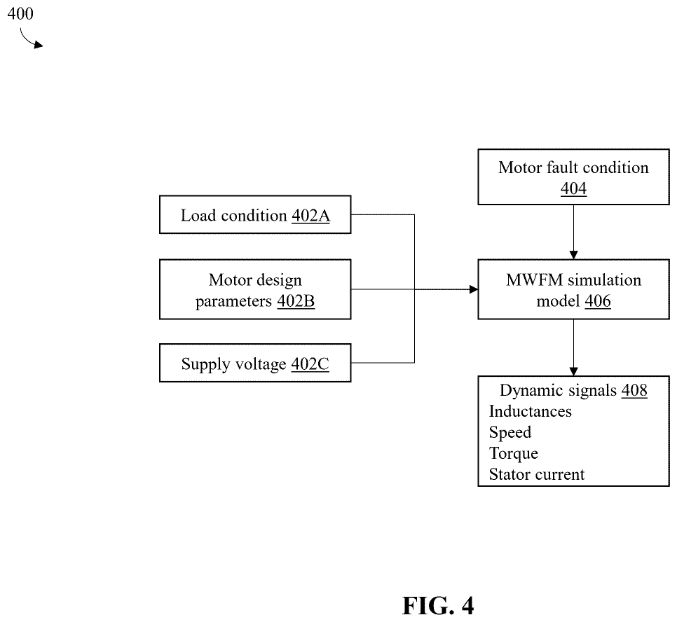

The synthetic data is generated using a coupled-circuit model combined with the Modified Winding Function Method (MWFM). The MWFM enables the calculation of the motor's inductance matrices under varying conditions, providing a more realistic representation of how motor faults impact electrical and mechanical characteristics. The MWFM is explained in detail with reference to FIG. 4. The synthetic data generation process involves modeling motor dynamics, electrical characteristics, and mechanical interactions to simulate fault-induced variations in vibration signals, current waveforms, and temperature profiles. The simulated fault conditions provide a controlled dataset that may be used for motor fault detection, especially in cases where real-world fault data is scarce. The generated synthetic data may be stored and made available for further processing.

At 154, the method 150 comprises obtaining real-world data representing at least one fault condition of the motor. The real-world data is collected from operational motors using vibration sensors, current sensors, temperature sensors, and acoustic sensors, among others. Each sensor captures a different modality of motor behavior: for example, vibration sensors monitor mechanical oscillations caused by structural faults, current sensors detect electrical anomalies associated with motor windings and rotor conditions, and temperature sensors track thermal variations that may indicate insulation failures. The collected real-world data is transmitted to the fault detection system 30 of FIG. 1A for preprocessing, which may include noise reduction, normalization, and feature extraction.

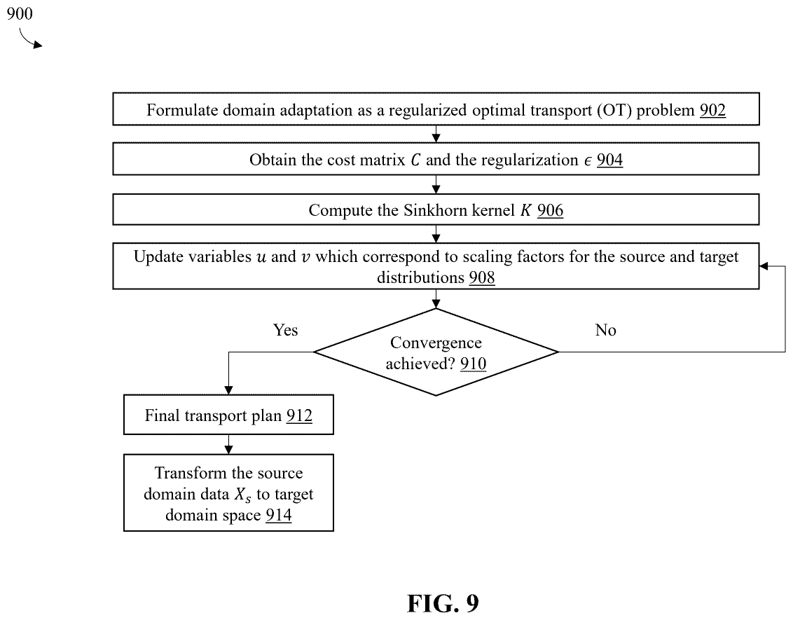

At 156, the system 50 applies a domain adaptation process to align a distribution of features in the synthetic data with the distribution of features in the real-world data. Due to differences in measurement conditions, modeling assumptions, and environmental factors, there is often a gap between simulated fault data and real-world sensor data. To bridge this gap, a optimal transport-based domain adaptation method is used. The method adjusts the synthetic data distribution to more closely match real-world conditions. By doing so, machine learning models trained on synthetic data may generalize effectively when deployed in real-world environments. The domain adaptation method is explained in detail with reference to FIG. 9. The domain-adapted data may be stored in the memory 116 of FIG. 1A and used for machine learning model training.

At 158, the method 150 comprises training a machine learning model using the domain-adapted synthetic data and/or real-world data. The machine learning model may be a neural network, support vector machine, decision tree, or another classification algorithm capable of distinguishing between different types of motor faults. The training involves providing the model with labeled fault data to learn distinguishing characteristics of different fault conditions. The trained machine learning model is validated using test data for accuracy and robustness in detecting motor faults under real-world conditions. The trained machine learning model may be deployed in the fault detection system 30 of FIG. 1A to continuously monitor motor health and provide early warnings of potential failures.

Additionally, in some embodiments, the method 150 may further comprise generating one or more control signals for controlling the motor, based on the motor fault data and submitting the control signals to the motor controller 124 of FIG. 1A. The motor controller 124 controls the motor in accordance with the one or more control signals. The one or more control signals may specify values of currents, voltages, or rotation speed of the motor. In some embodiments, the motor may be slowed down or stopped based on the type of the detected fault and/or the severity of the detected fault. Additionally, in some embodiments, the method 150 may further comprise generating one or more alerts based on the generated motor fault data. According to some embodiments, the method 150 may still further comprise generating one or more corrective actions to combat or address the detected fault. The one or more alerts and/or the corrective actions may be rendered through a suitable interface such as the user interface 118 of the fault detection system 30 of FIG. 1A.

FIG. 1C illustrates schematics of a system for fault detection in an induction motor at runtime, according to one embodiment. The system 50 of FIG. 1C is similar to the system 50 of FIG. 1A, with a key difference being that the machine learning model 116A which was included in memory 116 in FIG. 1A is now represented as a trained machine learning model 116C in the memory 116 in FIG. 1C. This distinction signifies the machine learning model 116A has already been trained and is now deployed for real-time fault detection. Similarly as FIG. 1A, the system includes memory 116, processor 112, sensors/control interface 114, user interface in the fault detection system 30.

FIG. 1D illustrates a flowchart of a method for motor fault detection using hybrid physics based and data driven method, according to some embodiments. FIG. 1D may be described in continuation of method 150 of FIG. 1B. FIG. 1D is described with reference to one or more elements from FIG. 1A. At 172, the method 170 comprises obtaining real-time operational data representing the operation of the electric motor. The real-time operational data may be collected from various sensors monitoring key motor parameters, such as vibration, current, voltage, temperature, and rotational speed. These sensors continuously capture data that reflects the motor's real-time performance and potential deviations from normal operating conditions. The acquired sensor data may be transmitted to the motor fault detection system 30 for further analysis. In some embodiments, the collected real time operational data may undergo preprocessing, including noise reduction, normalization, and feature extraction, to maintain accuracy of subsequent fault detection.

At 174, the method 170 comprises applying the real-time operational data to a trained machine learning model. The trained machine learning model, which was developed (explained in FIG. 1B) using both physics-based simulation data and real-world sensor data, analyzes the incoming real time operational data. The trained machine learning model has learnt patterns associated with various fault conditions and may recognize deviations indicative of potential issues. By leveraging domain adaptation techniques, the trained machine learning model aligns the real-time data with its learned representations, for fault detection despite variations in operating conditions. The real-time operational data serves as an input to the trained machine learning model, which processes to identify patterns and anomalies that may signify motor faults. For example, if the machine learning model was trained to detect broken rotor bar faults, it may analyze real-time current signals from the motor and identify specific frequency components (such as sidebands around the fundamental frequency) that are characteristic of the fault. Similarly, for bearing faults, the trained machine learning model may examine vibration signals and detect abnormal frequency peaks corresponding to bearing defect frequencies.

At 176, the method 170 comprises detecting one or more fault conditions in the motor based on the application of the trained machine learning model. The trained machine learning model classifies the real time operational data into different fault categories, such as bearing faults, broken rotor bars, eccentricity issues, or insulation degradation. Additionally, the trained machine learning model may assess the severity of detected faults by analyzing the magnitude and progression of fault indicators, enabling predictive maintenance and early intervention before critical (e.g., complete bearing seizure leading to shaft damage, rotor bar breakage causing motor stalling, severe insulation breakdown resulting in short circuits and fire hazards) failures occur. For instance, if a bearing fault is in its early stages, the system 50 may recommend periodic monitoring, whereas a severe bearing defect may trigger an urgent maintenance alert. The detected fault conditions may be stored, visualized through a user interface, or used to generate alerts and control signals for motor protection. In some embodiments, the method 170 may further comprise generating one or more control signals based on the detected faults, as well as recommending corrective actions to mitigate motor performance degradation.

For instance, if excessive rotor eccentricity is detected, the fault detection system 30 may suggest balancing procedures or load adjustments. If overheating is identified, the fault detection system 30 may recommend reducing the load or improving cooling mechanisms. The corrective actions may be displayed through an interface, allowing operators to take preventive measures or schedule maintenance as needed, ultimately improving the reliability and lifespan of the motor.

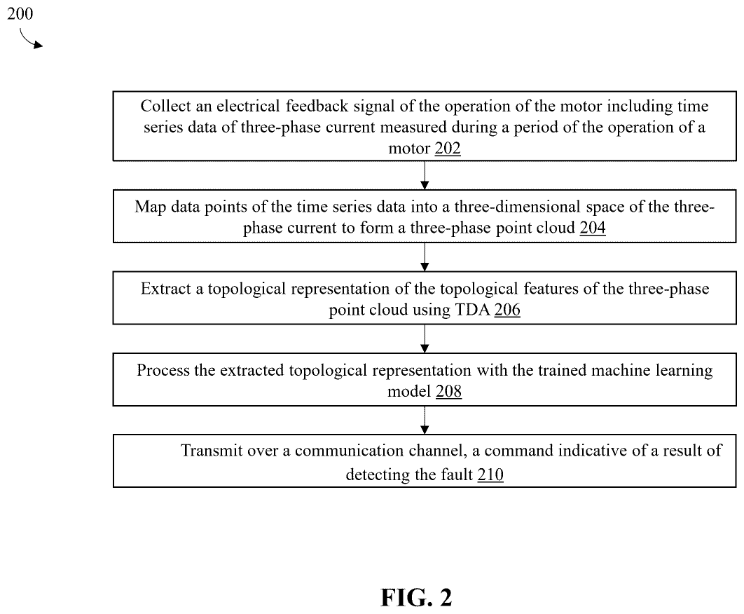

FIG. 2 illustrates a flowchart of a method for motor fault detection using Topological Data Analysis (TDA), according to some embodiments. FIG. 2 is described with reference to one or more elements from FIG. 1A. At 202, the method 200 comprises collecting an electrical feedback signal of the operation of the motor including time series data of three-phase current measured during a period of the operation of a motor. The time-series data of the three-phase current may be obtained from current sensors monitoring the motor's power supply. These sensors continuously capture variations in current flow during motor operation, providing real-time insights into motor health. The collected time series data may be transmitted over a wired or wireless communication channel to a fault detection system 30 for further analysis. The time series data provide insights into the motor's electrical behavior and may indicate abnormalities associated with various fault conditions.

At 204, the collected time-series data is mapped into a three-dimensional space of the three-phase current to form a three-phase point cloud. The three-phase point cloud is a mathematical representation of how the electrical behavior of the motor evolves over time. The trajectory of this point cloud encodes important information about the motor's dynamic behavior, and its shape may reveal hidden patterns, distortions, and anomalies that signify specific fault conditions. For example, a healthy motor typically exhibits a smooth, periodic trajectory in the point cloud. An unbalanced supply voltage distorts the trajectory, causing asymmetric patterns.

At 206, the method 200 extracts a topological representation of the topological features of the three-phase point cloud using the TDA. The system 50 applies topological data analysis (TDA) to the three-phase point cloud to extract topological features such as loops, clusters, and voids. TDA is applied to quantify persistent structures within the data of the motor fault, such as loops, clusters, and voids, which correspond to underlying fault signatures. The advantage of TDA is that it captures the intrinsic shape of the data, making resilient to noise and variations in operating conditions. For example, persistent homology techniques identify repetitive structures in the current waveform. Betti numbers and persistence diagrams are computed to characterize fault-specific topological features. A change in Betti numbers over time indicates the onset or progression of a fault. The topological features are extracted and formatted by the system 50 as structured data that preserves fault characteristics while reducing dimensionality, making easier for downstream analysis.

At 208, the system 50 process the extracted topological representation with the trained machine learning model. The extracted topological representation of the real-time three-phase current point cloud is fed into a trained machine learning model, which is pre-trained using both physics-based synthetic data (generated via motor simulation models) and real-world sensor data (collected from historical motor faults). The trained machine learning model recognize fault conditions by classifying the topological representation into predefined categories, such as bearing wear, broken rotor bars, stator winding faults, or voltage imbalance. The trained machine learning model further adapts to different operating conditions using domain adaptation techniques, guaranteeing that real-time data is aligned with previously learned fault patterns, even though there are slight variations in motor parameters or environmental conditions. The trained machine learning model further provide fault severity assessment, predicting the likelihood of failure progression, which allows for early maintenance interventions.

At 210, the method 200 comprises transmitting a command indicative of the detected fault over a communication channel. The command may be sent to a motor control system, a maintenance dashboard, or an alert system to notify operators of detected anomalies. The transmitted information may trigger alerts, control signals, or predictive maintenance actions. For example, a severe fault is detected, the system 50 may automatically adjust motor parameters, schedule maintenance, or initiate an emergency shutdown to prevent further damage.

In some embodiments, the method continuously updates the trained machine learning model by storing new fault data and retraining periodically, ensuring the system 50 improves over time and adapts to new types of faults.

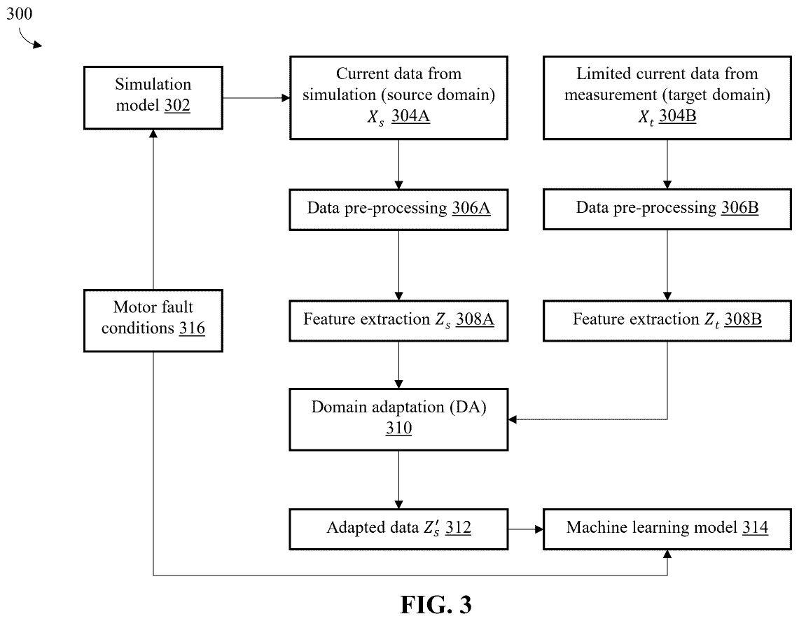

FIG. 3 illustrates a framework 300 for motor fault detection using hybrid physics based and data driven method, according to one embodiment. The framework 300 aims to extract, align, and fuse features from both simulation-generated synthetic data and real-world measured data. The framework 300 comprises simulation model 302, which receives motor fault conditions 316 as inputs. The motor fault conditions include load conditions (e.g., varying torque and mechanical load changes), motor design parameters (e.g., number of poles, winding resistance, and inductance), and supply voltage variations (e.g., voltage imbalance and harmonics). Based on the conditions, the simulation model 302 generates synthetic current data Xₛ304A representing motor behavior under different faulty scenarios. The Modified Winding Function Method (MWFM) is utilized for simulation model, which is described in FIG. 4. MWFM is a physics-based technique that models motor inductance variations under different fault scenarios, enabling precise computation of dynamic signals such as inductances, speed, torque, and stator currents. The computed signals are used to generate current data from simulation (source domain) Xₛ 304A, which represents the expected motor behavior under faulty conditions.

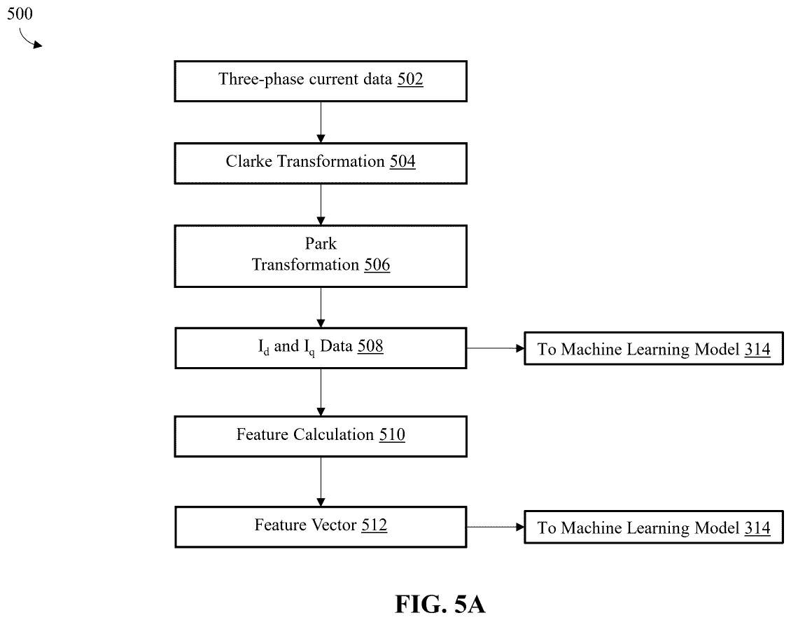

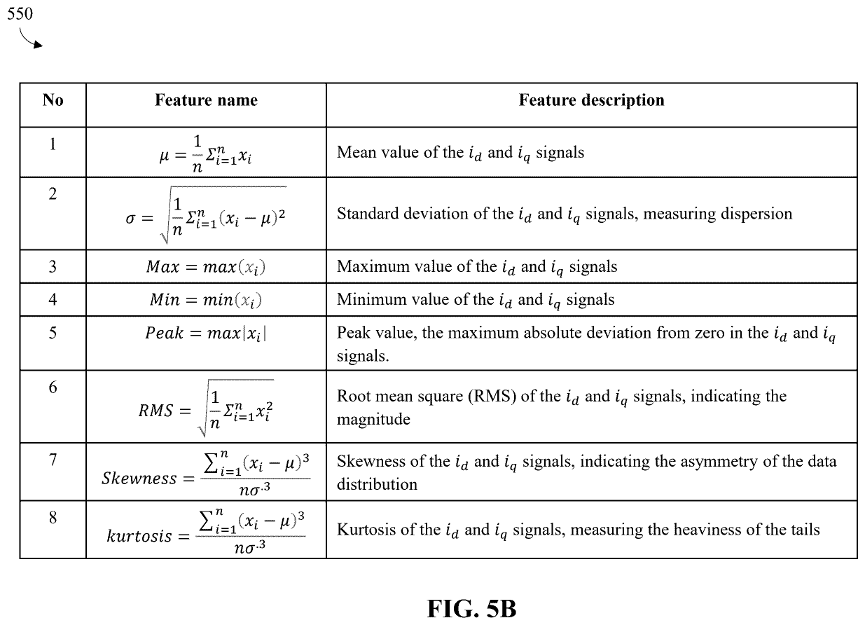

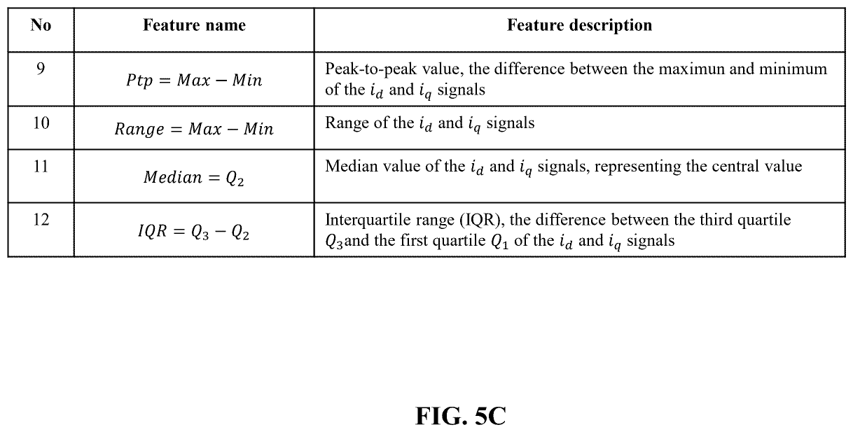

The current data from simulation (source domain) Xₛ304A undergoes pre-processing 306A, where signal conditioning, noise filtering, and normalization are applied. Feature extraction 308A is performed to obtain characteristics such as time-domain and frequency-domain representations. The pre processing and feature extraction for both current data 304A and limited current dara 304B is explained in FIGS. 5A, 6A, 7A and 8.

Limited current data from measurement (target domain) Xₜ 304B may be separately obtained from actual motor measurements in an industrial setting or laboratory environment. Unlike current data 304A, limited current data Xₜ 304B may be often limited due to practical constraints, such as sensor placement, variability in motor operating conditions, and the cost of acquiring labeled fault data. The limited current data Xₜ304B undergoes pre-processing 306B and feature extraction 308B to obtain meaningful representations of actual motor behavior.

A Domain Adaptation (DA) method 310 is used to align the extracted features from the current data (synthetic data) and the limited current data (real-world data), addressing discrepancies that arise due to differences between simulated and actual operating conditions. The domain adaptation 310 method is explained in FIG. 9. The domain adaptation 310 process produces adapted synthetic data Z′ₛ312, which better matches real-world conditions with the synthetic data. The machine learning model 314 is trained using the adapted synthetic data Z′ₛ312 and motor fault conditions 316 as labeled ground truth. Incorporating motor fault conditions 316 as an input allows the machine learning model 314 to learn associations between extracted features and specific fault categories, enhancing classification accuracy.

FIG. 4 illustrates a framework 400 of simulation process using MWFM method, according to one embodiment. FIG. 4 is described with reference to one or more elements from FIG. 1A. The framework 400 for motor fault simulation comprises Modified Winding Function Method (MWFM) 406, which is used for generating synthetic data representing motor behavior under various operating and fault conditions. The MWFM simulation model 406 receives multiple input parameters, including load conditions 402A, motor design parameters 402B, and supply voltage 402C, all of which influence the motor's dynamic performance. Load conditions 402A define external mechanical loads acting on the motor, such as variations in torque, load inertia, and sudden load changes, which influence motor performance. Motor design parameters 402B encompass electrical and physical characteristics, including winding resistance, inductance, and rotor-stator dimensions. The supply voltage 402C includes the electrical input, accounting for fluctuations in voltage magnitude, frequency variations, and phase imbalances.

Additionally, the motor fault conditions 404 introduce different fault scenarios such as broken rotor bars, eccentricity, shorted windings, and bearing failures, which affect the electrical and mechanical behavior of the motor. The MWFM simulation model 406 utilizes the inputs to compute inductance matrices at each time step, leveraging the integration of winding functions and air-gap permeance functions over all stator angles. The simulation process produces dynamic signals 408, including inductance variations, speed, torque, and stator current, all of which provide indicators of motor health. The dynamic signals are essential for fault diagnosis, as they reflect changes in motor performance due to faults.

### Simulation Model

Coupled-circuit model combined with modified winding function method (MWFM) has been implemented achieve good accuracy with reasonable complexity. The MWFM can be used to calculate the motor's inductance matrices at different conditions. The inductance between a pair of windings at each time step can be calculated by the integration of the product of the two winding functions and the air gap permeance function, over all stator angles. For winding i and winding j, the inductance is derived as

$$\begin{matrix}{L}_{ij} ( t ) = {μ}_{0} lr {\int }_{0}^{2 π} & {n}_{i} ( ϕ , t ) {M}_{j} ( ϕ , t ) {g}^{- 1} ( ϕ , t ) d ϕ\end{matrix} , \qquad ( 1 )$$

where μ₀ is the vacuum permeability, r is air gap radius, l is the stack length, nᵢ(φ, t) is the winding turns function for winding i, and Mⱼ(φ, t) is the modified winding function for winding j, which is calculated by

$$M ( ϕ , t ) = n ( ϕ , t ) - < M ( t ) > , \qquad ( 2 )$$

$$where$$

$$\begin{matrix}< M ( t ) >= \frac{1}{2 π 〈 {g}^{- 1} ( ϕ , t ) 〉} {\int }_{0}^{2 π} & n ( ϕ , t ) {g}^{- 1} ( ϕ , t ) d ϕ\end{matrix} , \qquad ( 3 )$$

$$\begin{matrix}< {g}^{- 1} ( ϕ , t ) >= \frac{1}{2 π} {\int }_{0}^{2 π} & {g}^{- 1} ( ϕ , t ) d ϕ\end{matrix} . \qquad ( 4 )$$

As can be observed from the above equations, the air gap function is essential in calculating the motor performance especially under eccentricity conditions, and needs to be described accurately.

For an ideal slot-less motor, the air gap is uniform with nominal size denoted as g₀. Static eccentricity makes the air gap asymmetric, and creates a time-invariant sinusoidal modulation to the air gap with amplitude given by δ_{SE}. Dynamic eccentricity, on the other hand, causes a time-varying modulation to the air gap, which is represented by another cosine function with amplitude δ_{DE}.

In addition, the slots in the stator and rotor effectively make the gap length larger than the nominal g₀. A Carter's coefficient K_{c} is used to represent this increase of average gap size. The value of Carter's coefficient can be calculated from the geometrical parameters of the motor, especially the slots.

Also, due to the nonlinear magnetic properties of iron core of motors, the permeability of the iron core is not a constant, but drops at higher flux density. This saturation effect makes the effective air gap size smaller, and also adds a time-dependent modulation to the air gap function. A common way to describe the saturation effect is to define a saturation factor kₛₐₜ as the ratio of fundamental components of the air gap voltage for motor at non-saturated and saturated conditions. The air gap modification due to saturation is describe as

$${g}_{s} ( ϕ , t ) = {g}_{1} [ 1 - ρcos ( 2 p ϕ - 2 {ω}_{r} t ) ] \qquad ( 5 )$$

where p is the pole pair number, φ is the stator angle, ωᵣ is the rotation speed, g₁ is the mean value of air gap length under saturation,

$${g}_{1} = {g}_{0} \frac{3 {k}_{sat}}{{k}_{sat} + 2} , \qquad ( 6 )$$

and ρ is the peak value of air gap fluctuation due to saturation,

$$ρ = \frac{2 ( {k}_{sat} - 1 )}{3 {k}_{sat}} \qquad ( 7 )$$

After taking these effects into consideration, the air gap function is now described as:

$$g ( ϕ , t ) = {g}_{s} {K}_{c} - {δ}_{SE} {g}_{0} cos ( ϕ ) - {δ}_{DE} {g}_{0} cos ( ϕ - {ω}_{r} t ) . \qquad ( 8 )$$

Bearing faults can also be described by periodic modulation of the air gap function. When a point defect of the bearing comes into contact with another bearing element, a radial displacement of the rotor center, or eccentricity is created. The periodic modification of the air gap length due to bearing fault induced eccentricity can be modeled by a series of Dirac delta functions. In presence of bearing fault, the air gap function of a motor at stator angle φ and time t is described by

$$g ( ϕ , t ) = {g}_{0} [ {K}_{c} - {e}_{0} cos ( ϕ + ψ ( t ) ) {\sum }_{k = - ∞}^{+ ∞} δ ( t - \frac{k}{{f}_{c}} ) ] , \qquad ( 9 )$$

where e₀ is the eccentricity level caused by the bearing fault, and ψ(t) is the defect position angle at time t. In practical implementation, rectangular shaped pulses with finite width are used instead of the pulses. The time-dependence of the fault position depends on the fault type. For outer race fault, the outer race stays in place at all time, and the fault position is fixed, ψ(t)=0 without loss of generality. For inner race fault, the fault rotates along with the inner race and rotor, so that ψ(t)=2πfᵣt.

Denote the resistance of each rotor bar as r_{b}, and the resistance of the end winding piece connecting two neighboring rotor bars as rₑ, the rotor resistance matrix can be written as equation (10).

In case of a broken bar fault, the corresponding bar is removed from the circuit system, and neighboring loops are combined as one new loop. The coupled-circuit equations update subsequently. The dimension of rotor resistance and inductance matrices is reduced from (N_{b}+1)×(N_{b}+1) to N_{b}×N_{b}, and the updated rotor resistance matrix with one broken bar is written in equation (11).

$${R}_{r} = {\underbrace{[ \begin{matrix}2 ( {r}_{b} + {r}_{e} ) & - {r}_{b} & 0 & 0 & … & - {r}_{b} & - {r}_{e} \\ - {r}_{b} & 2 ( {r}_{b} + {r}_{e} ) & - {r}_{b} & 0 & … & 0 & - {r}_{e} \\ 0 & - {r}_{b} & 2 ( {r}_{b} + {r}_{e} ) & - {r}_{b} & … & 0 & - {r}_{e} \\ ⋮ & ⋮ & ⋮ & ⋮ & ⋱ & ⋮ & ⋮ \\ - {r}_{b} & 0 & 0 & 0 & … & 2 ( {r}_{b} + {r}_{e} ) & - {r}_{e} \\ - {r}_{e} & - {r}_{e} & - {r}_{e} & - {r}_{e} & … & - {r}_{e} & {N}_{b} {r}_{e}\end{matrix} ]}}_{{N}_{b} + 1} \begin{matrix}\begin{matrix}\begin{matrix}\begin{matrix}\begin{matrix}1 \\ 2\end{matrix} \\ 3\end{matrix} \\ ⋮\end{matrix} \\ {N}_{b}\end{matrix} \\ {N}_{b} + 1\end{matrix} \qquad ( 10 )$$

$${R}_{r}^{′} = {\underbrace{[ \begin{matrix}2 ( {r}_{b} + {r}_{e} ) & - {r}_{b} & 0 & 0 & … & - {r}_{b} & - 2 {r}_{e} \\ - {r}_{b} & 2 ( {r}_{b} + {r}_{e} ) & - {r}_{b} & 0 & … & 0 & - {r}_{e} \\ 0 & - {r}_{b} & 2 ( {r}_{b} + {r}_{e} ) & - {r}_{b} & … & 0 & - {r}_{e} \\ ⋮ & ⋮ & ⋮ & ⋮ & ⋱ & ⋮ & ⋮ \\ - {r}_{b} & 0 & 0 & 0 & … & 2 ( {r}_{b} + {r}_{e} ) & - {r}_{e} \\ - 2 {r}_{e} & - {r}_{e} & - {r}_{e} & - {r}_{e} & … & - {r}_{e} & {N}_{b} {r}_{e}\end{matrix} ]}}_{{N}_{b}} \begin{matrix}\begin{matrix}\begin{matrix}\begin{matrix}\begin{matrix}1 \\ 2\end{matrix} \\ 3\end{matrix} \\ ⋮\end{matrix} \\ {N}_{b}\end{matrix} \\ \end{matrix} \qquad ( 11 )$$

The inductance terms also need to be updated accordingly. Broken bar fault is reflected in the stator current spectrum at side bands around the supply frequency:

$${f}_{BB} = ( 1 \pm 2 ks ) {f}_{s} , \qquad ( 12 )$$

where fₛ is the supply frequency, s is the slip of the induction motor, and k is an integer.

For dynamic simulation of the induction motor, the inductance terms are updated at each time step using the MWFM formulation. Coupled with the voltage, flux linkage, torque, and mechanical dynamics equations from circuit model, the full dynamic performance of the induction motor can be obtained.

For a three-phase squirrel-cage induction machine with rotor bar number R, the stator voltage and flux linkage are described by equations

$${V}_{s} = {R}_{s} {I}_{s} + \frac{d}{dt} {Λ}_{s} , \qquad ( 13 )$$

$${Λ}_{s} = {L}_{ss} {I}_{s} + {L}_{sr} {I}_{r} , \qquad ( 14 )$$

where Vₛ=[vₛ₁, vₛ₂, vₛ₃]^{T} is the stator voltage, Iₛ=[iₛ₁, iₛ₂, iₛ₃]^{T} is the stator current, Λₛ=[λₛ₁, λₛ₂, λₛ₃]^{T} is the stator flux linkage, Iᵣ=[iᵣ₁, iᵣ₂, . . . , ir_{R}, iₑ]^{T} is a vector of length R+1 to describe rotor loop currents and the end ring current respectively. Rₛ is a 3×3 stator resistance matrix, Lₛₛ is the 3×3 stator inductance matrix, and Lₛᵣ is the 3×(R+1) matrix containing mutual inductances between stator phases and rotor loops.

For the rotor side, the voltage equation and flux linkage equation are respectively

$${V}_{r} = {R}_{r} {I}_{r} + \frac{d}{dt} {Λ}_{r} , \qquad ( 15 )$$

$${Λ}_{r} = {L}_{rs} {I}_{s} + {L}_{rr} {I}_{r} , \qquad ( 16 )$$

where

$${L}_{rs} = {L}_{rs}^{T} ,$$

and Lᵣᵣ is the (R+1)×(R+1) self-inductance matrix of the rotor loops. Note that for squirrel cage rotors, the rotor voltages are zero: Vᵣ=[0,0, . . . ,0]^{T}.

The torque equation of the induction motor is

$${T}_{e} = \frac{1}{2} {I}_{s}^{⊤} \frac{\partial {L}_{ss}}{\partial {θ}_{r}} {I}_{s} + {I}_{s}^{⊤} \frac{\partial {L}_{sr}}{\partial {θ}_{r}} {I}_{r} + \frac{1}{2} {I}_{r}^{⊤} \frac{\partial {L}_{rr}}{\partial {θ}_{r}} {I}_{r} , \qquad ( 17 )$$

where θᵣ is the rotor's mechanical angle.

The mechanical dynamics of the motor is

$$\frac{d}{dt} {ω}_{r} = \frac{1}{J ( {T}_{e} - {T}_{L} )} , \qquad ( 18 )$$

$$\frac{d}{dt} {θ}_{r} = {ω}_{r} , \qquad ( 19 )$$

where ωᵣ is the mechanical speed, T_{L} is the load torque, and J is the inertia of the rotor. As we can see from the motor dynamic model, it is critical to obtain the inductance components in equations (14) and (16), and the inductance derivatives in equation (17). These values are computed using the MWFM models. We use the above modeling process to simulate induction motor with eccentricity faults.

FIG. 5A is a diagram illustrating a framework 500 for signal preprocessing and feature extraction process using DQ transformation, according to one embodiment. FIG. 4 is described with reference to one or more elements from FIG. 1A and FIG. 3. The framework 500 comprises three phase current data 502 which undergoes direct quadrature transformation of signal pre-processing

### Signal Pre-Processing

It is possible to apply the simulated data and real data of stator current in time domain directly for the simulation-to-real domain adaptation step. However, the fault signatures in stator current are typically very small and challenging to identify directly from the time-domain measurement data. To conduct the domain adaptation more effectively with limited data, it is often helpful to perform a signal pre-processing and feature extraction step. Various signal processing techniques can be utilized to transform the time-domain data, and fault-related features can be further extracted.

### DQ Transformation

The Direct-Quadrature Transformation (DQ Transformation) of three-phase currents is a mathematical method that converts three-phase alternating current (AC) signals into direct current (DC) form. This transformation converts the dynamic signals of a three-phase system into a rotating reference frame, where they appear as constant (DC-like) values under steady-state conditions on the rotating DQ axes, simplifying the control and analysis of these signals. The steps for DQ transformation process comprises of acquiring a three phase current data/signals 502 typically denoted as iₐ, i_{b}, and i_{c}. These signals represent the instantaneous values of the three-phase AC system and serve as the input for the DQ transformation. These signals are time-dependent and vary sinusoidally in balanced systems.

Further the DQ transformation process includes calculating the rotation angle θ. This angle defines the rotation of the reference frame relative to the fixed αβ frame, enabling the transformation of the signals. Typically, this angle is computed based on the system's angular velocity ωt, and dynamically adjusted using a phase-locked loop (PLL) to synchronize with the phase of the motor's rotating magnetic field.

The process further includes steps for Clarke transformation 504 which converts the three-phase signals 502 iₐ, i_{b}, and i_{c} into the αβ reference frame i_{α}, i_{β}. The matrix form of the Clarke transformation is:

$$[ \begin{matrix}{i}_{α} \\ {i}_{β} \\ {i}_{0}\end{matrix} ] = \frac{2}{3} [ \begin{matrix}1 & - \frac{1}{2} & - \frac{1}{2} \\ 0 & \frac{\sqrt{3}}{2} & - \frac{\sqrt{3}}{2} \\ \frac{1}{2} & \frac{1}{2} & \frac{1}{2}\end{matrix} ] [ \begin{matrix}{i}_{a} \\ {i}_{b} \\ {i}_{c}\end{matrix} ] \qquad ( 20 )$$

In a balanced system, the zero-sequence component i₀ is typically zero, so the simplified Clarke transformation is:

$$[ \begin{matrix}{i}_{α} \\ {i}_{β}\end{matrix} ] = [ \begin{matrix}1 & - \frac{1}{2} & - \frac{1}{2} \\ 0 & \frac{\sqrt{3}}{2} & - \frac{\sqrt{3}}{2}\end{matrix} ] [ \begin{matrix}{i}_{a} \\ {i}_{b} \\ {i}_{c}\end{matrix} ] \qquad ( 21 )$$

Once the final rotation angle θ_{final} is calculated (based on the system's angular velocity and PLL adjustment), the Park transformation 506 can be performed to convert the signals from the αβ coordinate system to the DQ coordinate system. The mathematical expression for this process is as follows:

$${i}_{d} = {i}_{α} cos ( {θ}_{final} ) + {i}_{β} sin ( {θ}_{final} ) \qquad ( 22 )$$

$${i}_{q} = - {i}_{α} sin ( {θ}_{final} ) + {i}_{β} cos ( {θ}_{final} ) \qquad ( 23 )$$

Here, θ_{final} is the compensated rotation angle, ensuring that the i_{d} component on the D axis is related to the magnetic flux, while the i_{q} component on the Q axis is related to the torque. The obtained i_{d} and i_{q} data 508 time series can be used for subsequent machine learning models directly. Alternatively, we can also extract certain features from these data, in order to reduce the dimension and improve the effectiveness of the method.

Once the i_{d} and i_{q} data/signals 508 are obtained, the process includes to extract meaningful features from these waveforms. The feature extraction process primarily includes feature calcultion process 510 which means calculating the mean of the i_{d} and i_{q} signals, respectively, and then subtract the mean from each signal to center the waveforms around zero, highlighting deviations and variations and making waveform analysis more precise. The feature extraction process includes extracting twelve primary statistical features: mean, standard deviation, maximum, minimum, peak, root mean square (RMS), skewness, kurtosis, peak-to-peak, range, median, and interquartile range (IQR), as detailed in FIGS. 5B and 5C. The extracted features reffered as feature vector 610 may be used for the machine learning model 314 and domain adaptation process.

FIGS. 5B and 5C jointly illustrates a table 550 of feature extraction from i_{d} and i_{q}signals, according to one embodiment. The table 550 includes twelve primary statistical features: mean, standard deviation, maximum, minimum, peak, root mean square (RMS), skewness, kurtosis, peak-to-peak, range, median, and interquartile range (IQR).

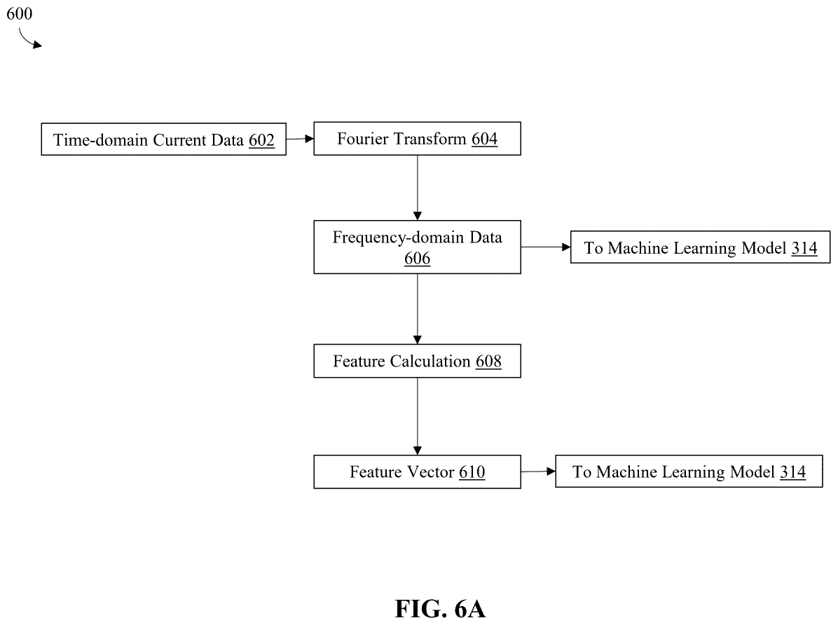

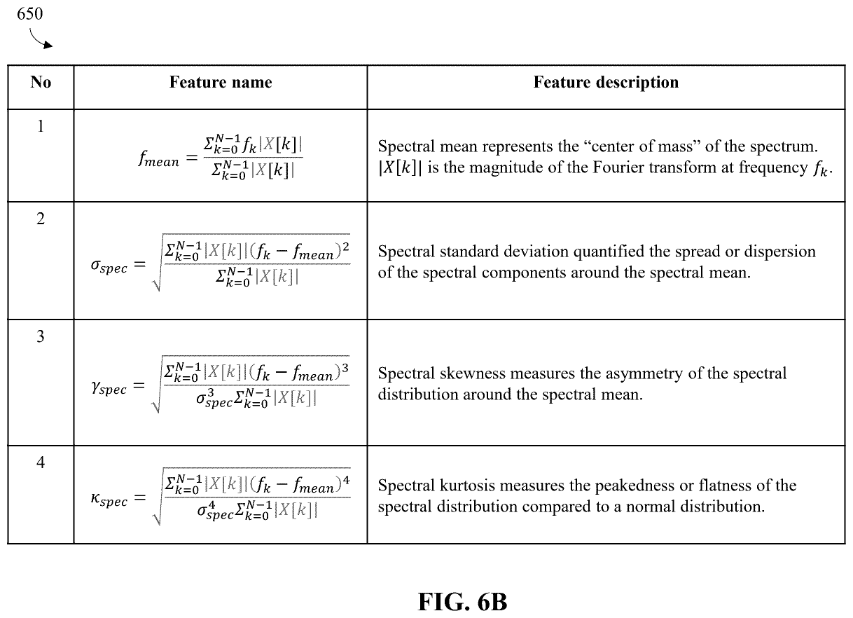

FIG. 6A is a diagram illustrating a framework 600 for signal preprocessing and feature extraction process using free spectrum analysis, according to some embodiments. The framework 600 includes an embodiment for signal preprocessing and feature extraction process to convert time domain current data 602 into frequency domain data 606 via Fourier transform 604.

### Fourier Transform

By examining the frequency spectrum of the stator current signals, the fault components may often be identified. The frequency-domain data may be fed into subsequent machine learning models for fault diagnosis. Alternatively, one can also extract certain statistical features from the frequency-domain data 606, such as spectral mean, standard deviation, skewness, and Kurtosis, as listed in FIG. 6B, Extracting of features include feature calculation 608 obtaining the feature vector 610 and feed the feature vector 610 into machine learning models 314 instead.

FIG. 6B illustrates a table 650 of features extracted from frequency spectrum, according to some embodiments. The table 650 includes four statistical measures: spectral mean, standard deviation, skewness, and Kurtosis.

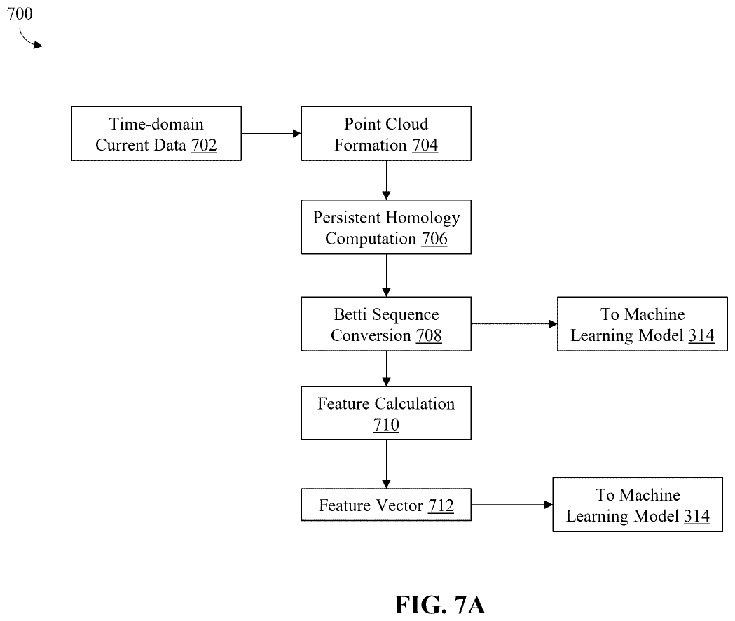

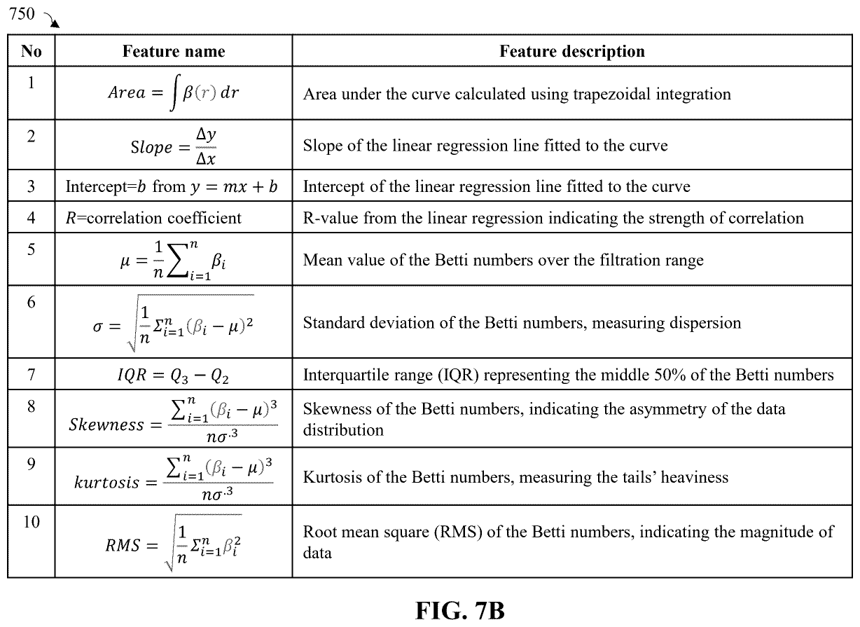

FIG. 7A is a diagram illustrating a framework 700 for signal preprocessing and feature extraction process using topological data analysis, according to one embodiment. The framework 600 includes an embodiment for signal preprocessing and feature extraction process to obtain persistent homology 706 of a data space from time domain current data 702.

### Topological Data Analysis

Topological data analysis (TDA) offers a numerical procedure to extract shape information from a given data space, such as connected components and holes. Generally, a few advantages make TDA very attractive for many challenging data analysis tasks: topological features are invariant under small and continuous deformations; they are also coordinate-free, and more robust against noises compared with other geometrical methods. In fact, in recent years, TDA is an actively pursued research area, and has been applied to a broad range of scientific problems, including image analysis, time-series data analysis, sensor networks, chemistry, material science, etc. These developments are largely enabled by a powerful tool named persistent homology.

The homology of a data space describes its topological features, such as connected components and holes, and persistent homology 706 computes those features that persist across different scales. To compute the persistent homology the steps include to represent a given data space with a point cloud 704, which is formed by a number of data points sampled from the data space or time domain current data 702. Different sampling and embedding techniques can be applied.

The steps further include identifying the simplicial complex of the point cloud, which is a collection of topological building blocks in different dimensions, or simplices, such as points, edges, triangles, etc. In particular, Rips complex is a commonly used algorithm to construct a simplicial complex, which assigns a threshold value or filtration radius r, and only includes complices with pair-wise Euclidean distance between their data points no larger than r.

The steps further include calculating homology Hᵢ, which counts the number of topological features from the constructed simplicial complex, where the subscript i denotes the dimension. For instance, H₀ counts the number of connected components, and H₁ counts the number of holes.

Lastly, persistent homology 706 is obtained through a filtration process of Rips complex, which computes the homology at different filtration radius r, and tracks the “birth” and “death” of each topological feature at the corresponding r. The evolution of homology across the whole range of r is recorded as persistent homology 706.

Multiple algorithms to perform Rips complexes filtration and persistent homology calculation have been developed, validated and implemented. Once calculated, persistent homology may be represented in different forms, and persistence diagram is a popular choice, which is composed of a set of points (b, d)|b, d∈ [symbol] \hat{ }2 andd>b, where each point corresponds to the “birth” and “death” of one topological feature. To be more specific, each point (b, d) denoted a topological feature being “born” at radius b and “dead” at radius d.

Persistence diagram may be transformed into other representations forms, such as persistence barcode, persistence landscape, and Betti sequence 708. In this disclosure, the extracted topological features of different data for data-driven models is used, and it is often convenient to have them represented as vectors of the same length to serve as input data. Betti sequence 708, or Betti curve is a representation that effectively achieves thee input data. Assume D is a persistence diagram with a finite number of off-diagonal points, with α=(b_{α}, d_{α}) a point in the diagram, and maximum filtration radius

$${r}_{max} > 0 et {\{ {r}_{i} \}}_{1}^{M}$$

be equally spaced points within [0, rₘₐₓ]he Betti sequence of D is a vector of length M defined as

$$\vec{β} = {( {β}_{i} )}_{1}^{M} ,$$

with the entries βᵢ count the number of points in the persistence diagram at filtration radius rᵢ. Define the function:

$${f}_{α} ( r ) = \{ \begin{matrix}1 , & {b}_{α} \leq r \leq {d}_{α} , \\ 0 , & otherwise ,\end{matrix}$$

Obtain the points on a Betti curve through the summation: βᵢ=Σ_{α∈D} f_{α}(rᵢ).

The obtained Betti sequences 708 may be used for the subsequent machine learning models 314. Alternatively, one may also extract statistical features referred as feature calculation 710 from these Betti sequences in order to reduce the dimension of the data, before feeding into the the subsequent machine learning models.

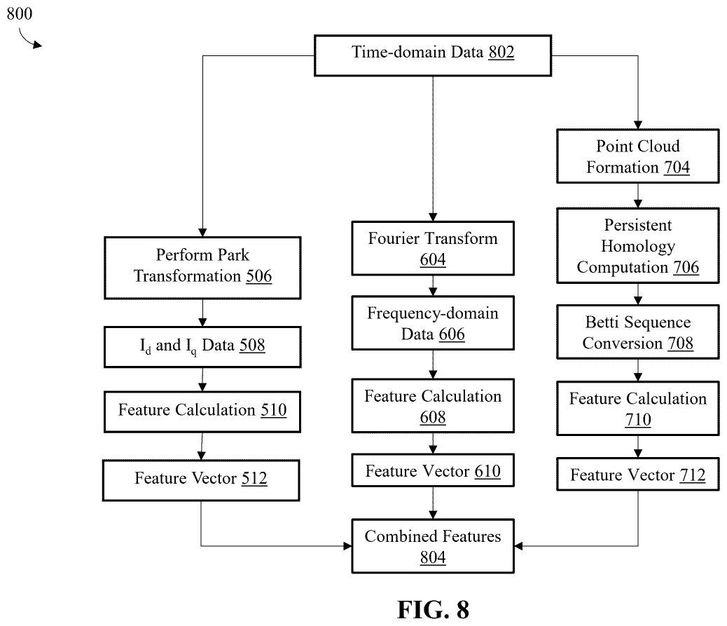

Statistical features from the H₀ and H₁ Betti Curves provide a quantitative analysis derived from the zeroth and first homological dimensions of the data set across varying filtration radius. These features include ten primary statistical measures: area, slope, intercept, R-value, mean, standard deviation, interquartile range (IQR), skewness, kurtosis, and root mean square (RMS), detailed in FIG. 7B. and feed the features referred as feature vector 712 to the machine learning model 314. Multiple signal process methods and subsequent feature extraction can be further combined, and all extracted features are used for the subsequent machine learning models, as shown in FIG. 8.

FIG. 7B illustrates a table 750 of features extracted from H₀ and H₁betti curves, according to one embodiment. The table 750 includes ten primary statistical measures: area, slope, intercept, R-value, mean, standard deviation, interquartile range (IQR), skewness, kurtosis, and root mean square (RMS),

FIG. 8 is a diagram illustrating a method of signal preprocessing and feature extraction, according to some embodiments. FIG. 8 includes a environment 800 which illustrates the integration of multiple signal preprocessing and feature extraction methods. The method include DQ transformtion which converts time domain data 802 into the the i_{d} and i_{q} data/signals 508 and followed by a feature extraction process that includes feature calculation 510 and feature vector 512, as explained in FIG. 5A.

The method further include fourier transform method, which converts time-domain data 802 into frequency-domain data 606, followed by a feature extraction process that includes feature calculation 608 and feature vector 610, as explained in FIG. 6A.

The methods further include topological data analysis (TDA) transformation, which transforms time-domain data 802 into persistent homology 706, followed by feature calculation 710 and feature vector 712, as explained in FIG. 7A.

The extracted features from each of the method are combined to form a set of combined feature 804. By integrating the diverse feature extraction techniques, the combined feature 804 enhances fault detection accuracy, ensuring the system 50 captures a wide range of potential failure modes. The extracted features are processed for domain adaptation, bridging the gap between simulated and real-world data. Furthermore, the combined feature 804 approach supports real-time fault detection by continuously processing incoming data and extracting meaningful features for classification.

FIG. 9 is a flowchart illustrating domain adaptation method 900 using optimal transport technique, according to some embodiments. FIG. 9 is described with reference to one or more elements from FIG. 1A.

### Domain Adaptation

The domain adaptation method is used to bridge the gap between the synthetic data obtained from simulations and the real data from experiment measurements. The goal of domain adaptation is to map the feature distributions from the source domain Ds to the target domain Dt, thereby reducing the distributional discrepancy between them. Features are extracted from both domains to create feature vectors Xₛ and Xₜ, which are subsequently aligned during the domain adaptation process. Mathematically, let:

$${X}_{s} = \{ ( {x}_{s}^{1} , {y}_{s}^{1} ) , ( {x}_{s}^{2} , {y}_{s}^{2} ) , … , ( {x}_{s}^{n} , {y}_{s}^{n} ) \} ∈ {D}_{s} , {y}_{s}^{i} ∈ {Y}_{s} \qquad ( 24 )$$

$${X}_{t} = \{ {x}_{t}^{1} , {x}_{t}^{2} , … , {x}_{t}^{n} \} ∈ {D}_{t} \qquad ( 25 )$$

Here, Xₛ contains n feature vectors from the simulation data, representing the source domain, and Yₛ is the set of labels. Xₜ contains m feature vectors from the real data, representing the target domain.

Domain adaptation methods can be broadly categorized into the various approaches including Discrepancy-Based Methods, which minimize the distribution divergence between the source and target domains by using statistical distance measures; Adversarial-Based Methods, which employ adversarial learning to make the feature representations of the source and target domains indistinguishable; Reconstruction-Based Methods, which use autoencoders or generative models to learn domain-invariant features through reconstruction; Self-Supervised and Pseudo-Labeling Methods, which use target domain data to refine predictions without requiring labeled target samples; Graph-Based and Manifold Alignment Methods, which align the geometric structure of feature spaces between domains.

Optimal transport is a Discrepancy-Based Method, which explicitly matches probability distributions by computing an optimal transport plan, and can provide a more accurate alignment of the source and target domains compared with other methods.

### Optimal Transport

Domain adaptation can be formulated as a regularized Optimal Transport (OT) problem 902, where an entropy term is added to the classic transport cost function to improve computational efficiency and promote smoother solutions:

$${γ}^{*} = arg {min}_{γ} {\sum }_{i , j} {γ}_{i , j} C ( {x}_{s}^{i} , {x}_{t}^{j} ) + ϵ {\sum }_{i , j} {γ}_{i , j} log ( {γ}_{i , j} ) \qquad ( 26 )$$

where γ represents the transport plan,

$$C ( {x}_{s}^{i} , {x}_{t}^{j} )$$

is the cost of transporting

$${x}_{s}^{i} to {x}_{t}^{j} ,$$

and ∈ is the regularization parameter that balances the transport cost and the entropy of the transport plan. The domain adaptation method further comprise obtainig the cost matrix C and the regularization ∈ 904. The pairwise distances between the source and target domain data points are captured by the cost matrix C, typically computed using the squared Euclidean distance:

$${C}_{i , j} = {‖ {x}_{s}^{i} - {x}_{t}^{j} ‖}^{2} \qquad ( 27 )$$

While equation (26) defines the theoretical Optimal Transport problem with entropy regularization, solving this problem directly is computationally intensive due to the high dimensionality of the data and the need for stability in finding the transport plan. To solve this problem, the Sinkhorn algorithm is computed 906 to efficiently solve the regularized Optimal Transport problem by iteratively adjusting the transport plan γ.

Using the cost matrix C and the regularization parameter ∈, the Sinkhorn kernel K is computed as:

$$K = exp ( - \frac{c}{ϵ} ) \qquad ( 28 )$$

The Sinkhorn algorithm iteratively updates the dual variables u and v 908, which correspond to scaling factors for the source and target distributions, respectively. The update process is performed alternately: first, u^{(k+1)} is updated based on the current v^{(k)}, and then v^{(k+1)} is updated using the newly computed u^{(k+1)}. This alternating process continues until convergence 910. The update rules are given by:

$${u}^{( k + 1 )} = \frac{r}{{Kv}^{( k )}} , {v}^{( k + 1 )} = \frac{c}{{K}^{T} {u}^{( k + 1 )}} \qquad ( 29 )$$

where r and c are uniform distribution vectors representing the source and target domains, respectively. These distributions are normalized so that their total sum equals 1, ensuring they satisfy the marginal constraints required for the optimal transport problem. After several iterations, the Sinkhorn algorithm converges, and the final transport plan γ* is obtained 912 if the covergence is achieved. This solution can be expressed as:

$${γ}^{*} = diag ( u ) K diag ( v ) \qquad ( 30 )$$

Equation (30) represents the output of the Sinkhorn algorithm, which provides an efficient numerical solution to the regularized Optimal Transport problem defined in equation (26). Using the computed transport plan γ*, the source domain data Xₛ is transformed into the target domain space 914: They are defined as:

$$r = \frac{1}{n} 1 , c = \frac{1}{m} 1 \qquad ( 31 )$$

where 1 is a vector of ones. Each element of r is

$$\frac{1}{n} ,$$

where n is the number of data points in the source domain, and each element of c is

$$\frac{1}{m} ,$$

where m is the number of data points in the target domain.

$${X}_{s}^{trans} = γ * {X}_{s} \qquad ( 32 )$$

This transformation aligns the source domain data with the distribution of the target domain. Next, we train a new regression model using the transported source domain data

$$\{ {X}_{s}^{trans} , {Y}_{s} \} ,$$

with the goal of improving predictive performance of the test data

$${y}_{s} = {f}_{s}^{trans} ( {X}_{s}^{trans} ) \qquad ( 33 )$$

The objective of this model is to improve the performance of predictions on the target domain by leveraging the mapped source domain data.

Finally, to evaluate the performance of the model, we use the target domain test data

$$\{ {X}_{t}^{test} , {y}_{t}^{ttest} \} .$$

Root Mean Squared Error (RMSE) is computed to quantify the prediction error:

$$RMSE = \sqrt{\frac{1}{n} {\sum }_{i = 1}^{n} {( {y}_{t}^{test , i} - {f}_{s}^{trans} ( {X}_{t}^{, test , i} ) )}^{2}} \qquad ( 34 )$$

Additionally, we compute the coefficient of determination R², which measures how well the model fits the target domain data:

$${R}^{2} = 1 - \frac{{\sum }_{i = 1}^{n} {( {y}_{t}^{test , i} - {f}_{s}^{trans} ( {X}_{t}^{, test , i} ) )}^{2}}{{\sum }_{i = 1}^{n} {( {y}_{t}^{test , i} - \overline{{y}_{t}^{test}} )}^{2}} \qquad ( 35 )$$

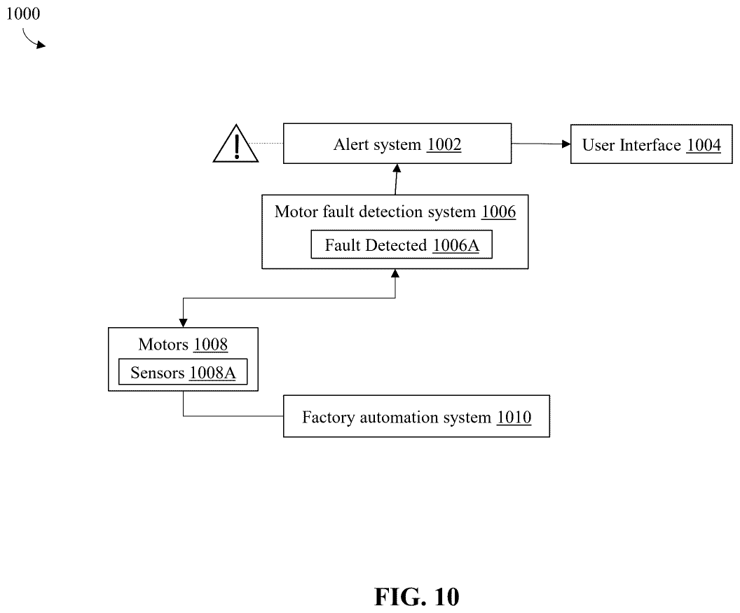

FIG. 10 illustrates a use case for motor fault detection in a factory automation system, according to one embodiment. The motor fault detection system 1006 continuously monitors the performance and health of motors 1008 through associated sensors 1008A. The sensors 1008A may include vibration sensors, temperature sensors, current sensors, or acoustic emission sensors, that generate measurement data indicative of motor faults. For instance, the motor fault detection system 1006 may utilize a vibration sensor to identify unusual patterns in the rotor's movement, or a temperature sensor to detect overheating due to increased friction or electrical issues.

The motor fault detection system 1006 upon identifying a fault, may trigger an alert within the alert system 1002. The alert system 1002 ensures that factory operators or supervisors are promptly informed about potential or ongoing faults. Alerts may be generated in various formats, such as visual signals on a control panel, auditory alarms, or digital notifications sent via connected devices. For instance, in a smart factory setup, an alert may be sent to an operator's mobile device or the central control room, facilitating immediate intervention.

The alert system 1002 may also communicate directly with the user interface 1004, which serves as a platform for operators to view detailed fault diagnostics. The user interface 1004 may display information, such as the fault's nature or type, severity level, location, and suggested corrective actions. For example, the alert system 1002 may indicate that an abnormal vibration in a motor's bearing has been detected, along with recommendations to inspect or replace the bearing. The factory automation system 1010 may integrate these fault detection capabilities into the broader industrial workflow. In some embodiments, when faults are detected, the factory automation system 1010 may take automated corrective actions to prevent further damage or disruption. For instance, the alert system 1002 may shut down the affected motor, reroute processes to backup machinery, or adjust production schedules to minimize downtime. The combination of motors 1008, sensors 1008A, and the motor fault detection system 1006 ensures a seamless and intelligent fault management process for the factory automation system 1010. This setup enhances operational efficiency, minimizes unplanned downtimes, and extends the lifecycle of machinery.

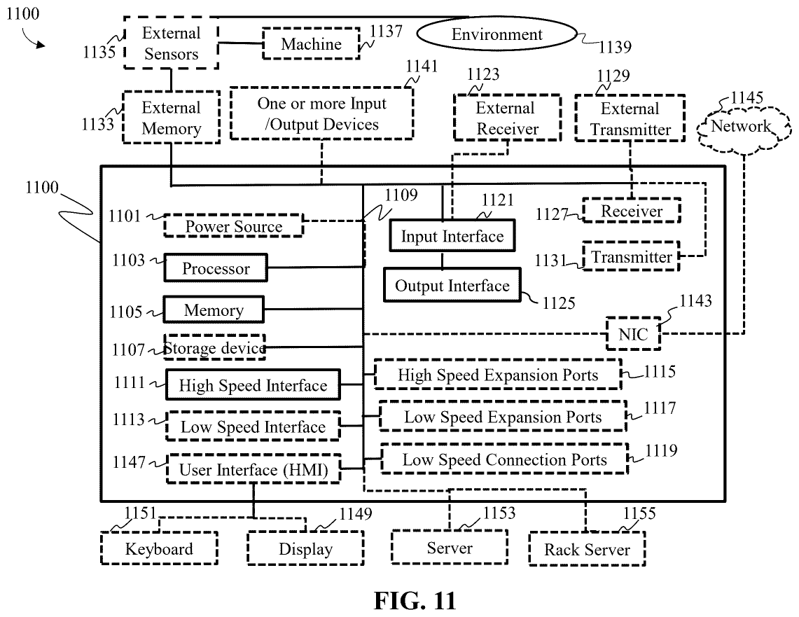

FIG. 11 shows a schematic diagram of some components of a control system 1100 for motor fault detection in a motor, in accordance with some embodiments. The control system 1100 includes a power source 1101, a processor 1103, a memory 1105, a storage device 1107, all connected to a bus 1109. Further, a high-speed interface 1111, a low-speed interface 1113, high-speed expansion ports 1115 and low speed connection ports 1117, can be connected to the bus 1109. In addition, a low-speed expansion port 1119 is in connection with the bus 1109. Further, an input interface 1121 can be connected via the bus 1109 to an external receiver 1123 and an output interface 1125. A receiver 1127 can be connected to an external transmitter 1129 and a transmitter 1131 via the bus 1109. Also connected to the bus 1109 can be an external memory 1133, external sensors 1135, machine(s) 1137, and an environment 1139. Further, one or more external input/output devices 1141 can be connected to the bus 1109. A network interface controller (NIC) 1143 can be adapted to connect through the bus 1109 to a network 1145, wherein data or other data, among other things, can be rendered on a third-party display device, third party imaging device, and/or third-party printing device outside of the control system 1100.

The memory 1105 may store instructions that are executable by the control system 1100 and any data that can be utilized by the methods and systems of the present disclosure. The memory 1105 can include random access memory (RAM), read only memory (ROM), flash memory, or any other suitable memory systems. The memory 1105 can be a volatile memory unit or units, and/or a non-volatile memory unit or units. The memory 1105 may also be another form of computer-readable medium, such as a magnetic or optical disk.

The storage device 1107 can be adapted to store supplementary data and/or software modules used by the control system 1100. The storage device 1107 can include a hard drive, an optical drive, a thumb-drive, an array of drives, or any combinations thereof. Further, the storage device 1107 can contain a computer-readable medium, such as a floppy disk device, a hard disk device, an optical disk device, or a tape device, a flash memory or other similar solid-state memory device, or an array of devices, including devices in a storage area network or other configurations. Instructions can be stored in an information carrier. The instructions, when executed by one or more processing devices (for example, the processor 1103), perform one or more methods, such as those described above.

The control system 1100 can be linked through the bus 1109, optionally, to a display interface or user Interface (HMI) 1147 adapted to connect the system 1100 to a display device 1149 and a keyboard 1151, wherein the display device 1149 can include a computer monitor, camera, television, projector, or mobile device, among others. In some implementations, the system 1100 may include a printer interface to connect to a printing device, wherein the printing device can include a liquid inkjet printer, solid ink printer, large-scale commercial printer, thermal printer, UV printer, or dye-sublimation printer, among others.

The high-speed interface 1111 manages bandwidth-intensive operations for the control system 1100, while the low-speed interface 1113 manages lower bandwidth-intensive operations. Such allocation of functions is an example only. In some implementations, the high-speed interface 1111 can be coupled to the memory 1105, the user interface (HMI) 1145, and to the keyboard 1151 and the display 1149 (e.g., through a graphics processor or accelerator), and to the high-speed expansion ports 1115, which may accept various expansion cards via the bus 1109. In an implementation, the low-speed interface 1113 is coupled to the storage device 1107 and the low-speed expansion ports 1117, via the bus 1109. The low-speed expansion ports 1117, which may include various communication ports (e.g., USB, Bluetooth, Ethernet, wireless Ethernet) may be coupled to the one or more input/output devices 1141. The control system 1100 may be connected to a server 1153 and a rack server 1155. The control system 1100 may be implemented in several different forms. For example, the control system 1100 may be implemented as part of the rack server 1155.

The above description provides exemplary embodiments only, and is not intended to limit the scope, applicability, or configuration of the disclosure. Rather, the above description of the exemplary embodiments will provide those skilled in the art with an enabling description for implementing one or more exemplary embodiments. Contemplated are various changes that may be made in the function and arrangement of elements without departing from the spirit and scope of the subject matter disclosed as set forth in the appended claims.

Specific details are given in the above description to provide a thorough understanding of the embodiments. However, understood by one of ordinary skill in the art can be that the embodiments may be practiced without these specific details. For example, systems, processes, and other elements in the subject matter disclosed may be shown as components in block diagram form in order not to obscure the embodiments in unnecessary detail. In other instances, well-known processes, structures, and techniques may be shown without unnecessary detail in order to avoid obscuring the embodiments. Further, like reference numbers and designations in the various drawings indicated like elements.

Also, individual embodiments may be described as a process which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process may be terminated when its operations are completed but may have additional steps not discussed or included in a figure. Furthermore, not all operations in any particularly described process may occur in all embodiments. A process may correspond to a method, a function, a procedure, a subroutine, a subprogram, etc. When a process corresponds to a function, the function's termination can correspond to a return of the function to the calling function or the main function.

Furthermore, embodiments of the subject matter disclosed may be implemented, at least in part, either manually or automatically. Manual or automatic implementations may be executed, or at least assisted, through the use of machines, hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

Various methods or processes outlined herein may be coded as software that is executable on one or more processors that employ any one of a variety of operating systems or platforms. Additionally, such software may be written using any of a number of suitable programming languages and/or programming or scripting tools, and also may be compiled as executable machine language code or intermediate code that is executed on a framework or virtual machine. Typically, the functionality of the program modules may be combined or distributed as desired in various embodiments.

Embodiments of the present disclosure may be embodied as a method, of which an example has been provided. The acts performed as part of the method may be ordered in any suitable way. Accordingly, embodiments may be constructed in which acts are performed in an order different than illustrated, which may include performing some acts concurrently, even though shown as sequential acts in illustrative embodiments. Although the present disclosure has been described with reference to certain preferred embodiments, it is to be understood that various other adaptations and modifications can be made within the spirit and scope of the present disclosure. Therefore, it is the aspect of the append claims to cover all such variations and modifications as come within the true spirit and scope of the present disclosure.

What is claimed is:

1. A method for detecting faults in operations of an electric motor, wherein the method uses a processor coupled with stored instructions implementing the method, wherein the instructions, when executed by the processor carry out steps of the method, comprising:
generating synthetic data representing fault conditions of the motor using a physics-based simulation model;
obtaining real-world data representing at least one fault condition of the motor;
applying a domain adaptation process to align a distribution of features in the synthetic data with a distribution of features in the real-world data;
training a machine learning model using the domain-adapted synthetic data and/or real-world data; and
detecting fault conditions in the motor by applying the trained machine learning model to real-time operational data representing the operations of the electric motor.

2. The method of claim 1, wherein the features of the synthetic data and the features of the real-world data include topological features produced by topological data analysis (TDA) of time-series data of motor signals, and wherein detecting the fault conditions comprises:
collecting, over a communication channel including one or a combination of a wired and wireless communication link, an electrical feedback signal of the operation of the motor including time series data of three-phase current measured during a period of the operation of a motor;
mapping data points of the time series data into a three-dimensional space of the three-phase current to form a three-phase point cloud;
extracting a topological representation of the topological features of the three-phase point cloud using the TDA;
processing the extracted topological representation with the trained machine learning model; and
transmitting, over the communication channel, a command indicative of a result of detecting the fault.

3. The method of claim 1, wherein the domain adaptation process uses optimal transport to minimize the distributional discrepancy between the synthetic and real-world data.

4. The method of claim 2, wherein the TDA process involves generating Betti curves from time-series data and extracting statistical features, including area under a curve, slope, intercept, and root mean square.

5. The method of claim 1, wherein the physics-based simulation model is configured to simulate motor faults including eccentricity, rotor bar damage, or bearing faults.

6. The method of claim 2, wherein the machine learning model is a regression model using support vector regression with a radial basis function kernel to predict fault severity levels.

7. The method of claim 1, further comprising:
preprocessing real-world data to reduce noise and enhance signal components related to fault conditions.

8. The method of claim 1, wherein the domain adaptation process utilizes a combination of synthetic data representing multiple fault levels and real-world data representing boundary fault levels to generate a hybrid dataset.

9. A system for motor fault detection, comprising:
a simulation module configured to generate synthetic data representing fault conditions;
a data acquisition module configured to collect real-world data for a motor under fault conditions;
a feature extraction module configured to process time-series data using topological data analysis;
a domain adaptation module configured to align features of synthetic data with real-world data;
a machine learning module configured to train a predictive model using the adapted synthetic data and real-world data; and
a fault detection module configured to detect fault conditions in the motor using the trained predictive model.

10. The system of claim 9, wherein the feature extraction module uses topological data analysis (TDA) to generate Betti curves and derive statistical features related to motor faults.
